(19) United States
(12) Patent Application Publication
(10) Pub. No.: US 2023/0012042 A1
(43) Pub. Date: Jan. 12, 2023

(54) APPARATUS FOR MANUFACTURING DISPLAY APPARATUS, METHOD OF MEASURING DROPLET, AND METHOD OF MANUFACTURING DISPLAY APPARATUS

(71) Applicant: Samsung Display Co., Ltd., Yongin-si (KR)

(72) Inventors: Cheho Lim, Yongin-si (KR); Dongjun Lee, Yongin-si (KR); Kangsoo Han, Yongin-si (KR); Sangyeon Hwang, Yongin-si (KR); Jeongwon Han, Yongin-si (KR)

(21) Appl. No.: 17/861,019

(22) Filed: Jul. 8, 2022

(30) Foreign Application Priority Data
Jul. 12, 2021 (KR) 10-2021-0091225

(51) Int. Cl. H01L 21/66; H01L 51/00; H01L 27/32; B41M 3/00; G01N 15/06

(52) U.S. Cl. CPC H01L 22/24; H01L 51/0001; H01L 27/322; B41M 3/003; G01N 15/06; G01N 2015/0693

(57) ABSTRACT

A method of manufacturing a display apparatus, the method includes supplying, from an ejector, a droplet onto a plane, capturing an image of the droplet, calculating a first luminance of a first area of the plane, the first area including a planar area of the droplet, and calculating a concentration of particles contained in the droplet based on the first luminance.

### CROSS-REFERENCE TO RELATED APPLICATION

This application claims priority to and the benefit of Korean Patent Application No. 10-2021-0091225, filed on Jul. 12, 2021, in the Korean Intellectual Property Office (KIPO), the entire content of which is incorporated by reference herein.

### BACKGROUND

### 1. Field

One or more embodiments of the present disclosure relate to an apparatus and method, and more particularly, to an apparatus for manufacturing a display apparatus, a method of measuring a droplet, and a method of manufacturing a display apparatus.

### 2. Description of the Related Art

Mobility-based electronic devices are widely used. Recently, tablet personal computers (PCs), in addition to small electronic devices such as mobile phones, have been widely used as mobile electronic devices.

A mobile electronic device includes a display apparatus to provide various functions, for example, visual information such as an image, to a user. Recently, the proportion of a display apparatus in an electronic device has gradually increased, and structures that are bendable to have certain angles have been developed.

A display apparatus may include various layers, and various processes may be used to form the various layers. In particular, at least one layer may be stacked or a structure may be formed through a printing process from among the various layers of the display apparatus. During the printing process, factors such as a resolution of the display apparatus are determined depending on how a pattern of droplets is formed, and accordingly, it is common to discharge droplets to a test table in advance and then to a substrate.

### SUMMARY

Aspects of one or more embodiments of the present disclosure are directed toward a method of measuring a droplet which may accurately measure a concentration of particles contained in a droplet by measuring a luminance of the droplet through an image of at least one test table.

Aspects of one or more embodiments of the present disclosure are directed toward a method and apparatus for manufacturing a display apparatus which may eject a droplet having an accurate particle concentration to a substrate by reflecting (or taking into consideration) the accurately measured concentration of particles.

Additional aspects will be set forth in part in the description which follows and, in part, will be apparent from the description, or may be learned by practice of the presented embodiments.

According to one or more embodiments, a method of manufacturing a display apparatus includes supplying, from an ejector, a droplet onto a plane, capturing an image of the droplet, calculating a first luminance of a first area of the plane, the first area including a planar area of the droplet, and calculating a concentration of particles contained in the droplet based on the first luminance.

The method may further include calculating a second luminance of a second area of the plane.

The concentration of the particles contained in the droplet may be calculated based on a correction luminance obtained by dividing the first luminance by the second luminance.

The second area may be an area where the droplet is not located.

A planar shape of the second area may correspond to a planar shape of the first area.

The second area may be an entire area of the plane including the first area.

The first area may include an edge having a planar shape of the droplet.

An edge of the planar area of the droplet is located inside the first area. The first area is larger in area than the planar area of the droplet.

The method may further include defining a third area located inside the first area, and calculating the first luminance of the first area excluding the third area.

The third area may be an area where reflection occurs.

The first luminance may be an average luminance of the first area.

The method may further include controlling an operation of the ejector according to the concentration of the particles.

The plane may be a plane of a test member or a plane of a display substrate.

The method may further include ejecting another droplet onto the display substrate based on the concentration of the particles contained in the droplet.

The droplet may include quantum dots.

The method may further include forming a color filter.

The method may further include ejecting droplets having different concentrations onto a same portion of the display substrate.

The ejector may include a plurality of nozzles. A concentration of a respective one of droplets is calculated for each of the plurality of nozzles.

Droplets may be supplied to a same portion of the display substrate through at least two nozzles from among the plurality of nozzles, the at least two nozzles having different particle concentrations in the respective ones of the droplets.

A plurality of ejectors may be provided. A concentration of a respective one of droplets is calculated for each of the plurality of ejectors.

Droplets may be supplied to a same portion of the display substrate through at least two ejectors from among the plurality of ejectors, the at least two ejectors having different particle concentrations in the respective ones of the droplets.

According to one or more embodiments, a method of manufacturing a display apparatus includes ejecting a droplet onto a plane through each of a plurality of nozzles and capturing an image of the droplet, setting a first area including the droplet in the image, calculating a first luminance of the first area, setting a second area different from the first area on the plane, and calculating a second luminance of the second area, calculating a correction luminance by using the first luminance and the second luminance, and calculating a concentration of particles contained in the droplet ejected through each of the plurality of nozzles based on the correction luminance, supplying droplets multiple times to a first portion and a second portion of a display substrate respectively corresponding to a first emission area and a second emission area that are located at different positions to emit light of a same color, to form a first layer on the first portion and a second layer on the second portion, and selecting a nozzle through which a droplet is supplied to the first emission area or the second emission area from among the plurality of nozzles based on the correction luminance of the droplet ejected through each nozzle so that, when the first layer and the second layer are formed, a concentration of particles contained in the first layer and a concentration of particles contained in the second layer are uniform.

The method may further include calculating the first luminance of the first area excluding a third area that is located inside the first area and where reflection occurs.

The droplet may include quantum dots.

The particles may include scatterers.

A planar area of the droplet is located inside the first area. The first area is equal to or larger than the planar area of the droplet.

The correction luminance may be calculated by dividing the first luminance by the second luminance.

According to one or more embodiments, an apparatus for manufacturing a display apparatus includes a test table adapted to support a test member or a substrate, the test member or the substrate being adapted to receive a droplet, a measurer spaced from the test table, the measurer being configured to capture an image of the droplet on the substrate or the test member, and a controller configured to calculate a first luminance of a first area including a planar area of the droplet based on the image of the droplet captured by the measurer, and to calculate a concentration of particles in the droplet based on the first luminance of the first area.

The controller may be further configured to calculate a correction luminance by dividing the first luminance by a second luminance of a second area of the test member or a second luminance of a second area of the substrate, and to calculate the concentration of the particles in the droplet based on the correction luminance.

The apparatus may further include an ejector configured to eject the droplet.

The controller may be further configured to control an operation of the ejector according to the concentration of the particles in the droplet.

A planar area of the droplet in the image may be located inside the first area.

A planar shape of the droplet in the image corresponds to a planar shape of the first area.

The controller may be further configured to calculate a luminance of the first area excluding a third area that is located inside the first area.

The third area may be an area where light emitted from the measurer is reflected by the droplet.

According to one or more embodiments, a method of measuring a droplet includes measuring a first luminance of a first area including a planar area of a droplet located in a plane, and calculating a concentration of particles contained in the droplet based on the first luminance.

The method may further include calculating a second luminance of a second area located in the plane.

A correction luminance may be calculated by dividing the first luminance by the second luminance, and the concentration of the particles in the droplet may be calculated based on the correction luminance.

A planar area of the droplet in an image may be located inside the first area.

A planar shape of the droplet in an image may correspond to a planar shape of the first area.

The first luminance of the first area excluding the third area that is located inside the first area may be calculated.

Other features and advantages of the disclosure will become more apparent from the drawings, the claims, and the detailed description.

These general and specific embodiments may be implemented by using a system, a method, a computer program, or a combination thereof.

### BRIEF DESCRIPTION OF THE DRAWINGS

The above and other aspects, features, and advantages of certain embodiments will be more apparent from the following description taken in conjunction with the accompanying drawings, in which:

FIG. 1 is a plan view illustrating a display apparatus, according to one or more embodiments;

FIG. 2 is a cross-sectional view illustrating a part of the display apparatus of FIG. 1;

FIG. 3 is a cross-sectional view illustrating a part of a display apparatus, according to one or more embodiments;

FIG. 4 is a cross-sectional view illustrating a part of a display apparatus, according to one or more embodiments;

FIG. 5 is a perspective view illustrating an apparatus for manufacturing a display apparatus, according to one or more embodiments;

FIG. 6 is a perspective view illustrating a test table of FIG. 5;

FIGS. 7A through 7C are plan views illustrating a part of a test member of FIG. 6;

FIG. 8A through FIG. 8D are graphs illustrating a relationship between a particle concentration and a correction luminance;

FIG. 9 is a perspective view illustrating an apparatus for manufacturing a display apparatus, according to one or more embodiments;

FIG. 10 is a rear view illustrating a first ejector of FIG. 1;

FIGS. 11A and 11B are cross-sectional views illustrating a method of manufacturing a display apparatus, according to one or more embodiments;

FIGS. 12A and 12B are cross-sectional views illustrating a method of manufacturing a display apparatus, according to one or more embodiments; and

FIGS. 13A and 13B are cross-sectional views illustrating a method of manufacturing a display apparatus, according to one or more embodiments.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present disclosure. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in more detail with reference to the drawings. However, the disclosure is not limited to the following embodiments and may be embodied in various forms.

Hereinafter, embodiments will be described in more detail with reference to the accompanying drawings, wherein the same or corresponding elements are denoted by the same reference numerals throughout and a repeated description thereof may not be repeated.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “including,” “having,” and “comprising” are intended to indicate the existence of the features or elements described in the specification, and are not intended to preclude the possibility that one or more other features or elements may exist or may be added.

Further, the use of “may” when describing embodiments of the present disclosure refers to “one or more embodiments of the present disclosure.”

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or contracted for convenience of explanation. For example, because sizes and thicknesses of elements in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the drawings, the relative sizes of elements, layers, and regions may be exaggerated and/or simplified for clarity. Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially,” “about,” and similar terms are used as terms of approximation and not as terms of degree, and are intended to account for the inherent deviations in measured or calculated values that would be recognized by those of ordinary skill in the art.

When a certain embodiment may be implemented differently, a specific process order may be different from the described order. For example, two consecutively described processes may be performed substantially at the same time or may be performed in an order opposite to the described order.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

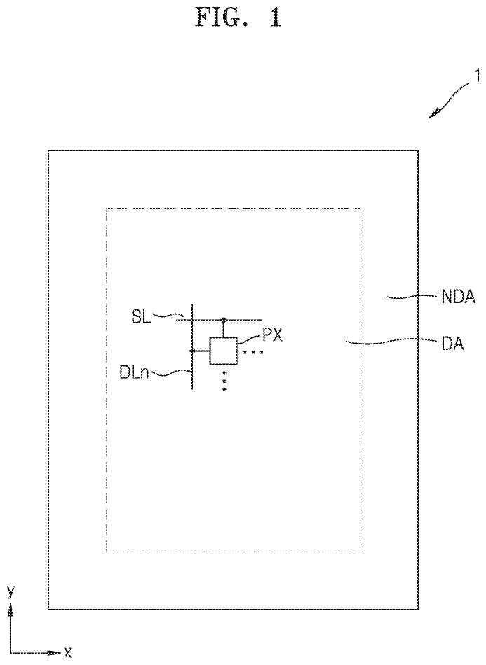

FIG. 1 is a plan view illustrating a display apparatus, according to one or more embodiments.

Referring to FIG. 1, a display apparatus 1 includes a display area DA where an image is formed and a non-display area NDA (e.g., a non-display area NDA around or surrounding the display area DA) where an image is not formed. The display apparatus 1 may provide an image by using light emitted by a plurality of pixels PX arranged in the display area DA. Each of the pixels PX may emit red light, green light, blue light, or white light. In this case, a plurality of pixels PX may be arranged in the display area DA to be spaced from one another.

The display apparatus 1 that is a device for displaying an image may be a portable mobile device such as a game player, a multimedia device, or a mini PC. Examples of the display apparatus 1 described below may include a liquid-crystal display, an electrophoretic display, an organic light-emitting display, an inorganic light-emitting display, a field-emission display, a surface-conduction electron-emitter display, a quantum dot display, a plasma display, and a cathode ray display. Although the display apparatus 1 that is manufactured by an apparatus for manufacturing a display apparatus according to one or more embodiments is an organic light-emitting display apparatus, embodiments of the present disclosure may be used to manufacture various suitable types of display apparatuses such as the types described above.

Each of the pixels PX may be connected (e.g., electrically connected) to a scan line SL and a data line DLn. The scan line SL may extend in an x direction, and the data line DLn may extend in a y direction.

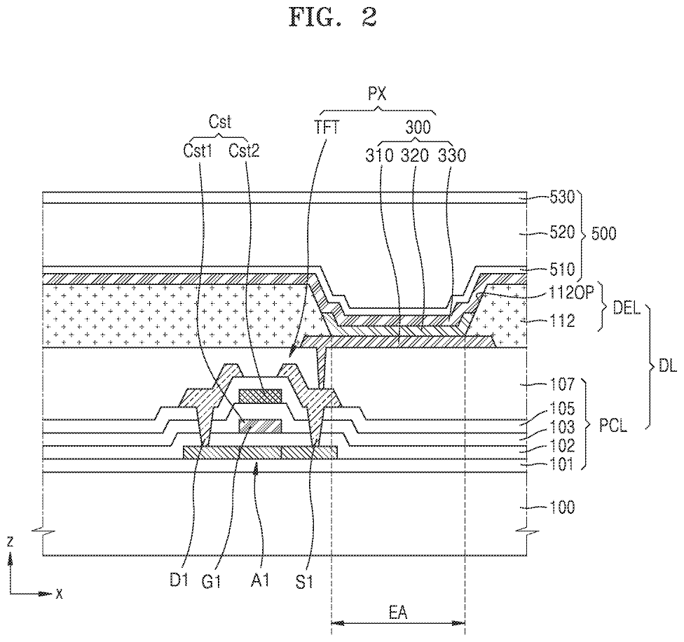

FIG. 2 is a cross-sectional view illustrating a part of the display apparatus of FIG. 1.

Referring to FIG. 2, a display layer DL and a thin-film encapsulation layer 500 may be located on a substrate 100. The display layer DL may include a pixel circuit layer PCL and a display element layer DEL.

The substrate 100 may include glass or a polymer resin such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

A barrier layer may be further provided between the display layer DL and the substrate 100. The barrier layer for preventing or reducing penetration of an external foreign material may have a single layer or multi-layer structure including an inorganic material such as silicon nitride (SiNₓ, x>0) or silicon oxide (SiOₓ, x>0).

The pixel circuit layer PCL is located on the substrate 100. In FIG. 2, the pixel circuit layer PCL includes a thin-film transistor TFT, and a buffer layer 101, a first gate insulating layer 102, a second gate insulating layer 103, an interlayer insulating layer 105, and a planarization layer 107 located under and/or over elements of the thin-film transistor TFT.

The buffer layer 101 may include an inorganic insulating material such as silicon nitride, silicon oxynitride, or silicon oxide, and may have a single layer or multi-layer structure including the above inorganic insulating material.

The thin-film transistor TFT may include a semiconductor layer A1, and the semiconductor layer A1 may include polysilicon. Alternatively, the semiconductor layer A1 may include amorphous silicon, an oxide semiconductor, or an organic semiconductor. The semiconductor layer A1 may include a channel region, and a drain region and a source region located on or at opposite sides of the channel region.

A gate electrode G1 may overlap the channel region. The gate electrode G1 may include a low-resistance metal material. The gate electrode G1 may include a conductive material including molybdenum (Mo), aluminum (Al), copper (Cu), or titanium (Ti), and may have a single layer or multi-layer structure including the above material.

The first gate insulating layer 102 between the semiconductor layer A1 and the gate electrode G1 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). ZnOₓ may include zinc oxide (ZnO) and/or zinc peroxide (ZnO₂).

The second gate insulating layer 103 may cover the gate electrode G1. The second gate insulating layer 103 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ), like the first gate insulating layer 102. Zinc Oxide (ZnOₓ) may be zinc oxide (ZnO) and/or zinc peroxide (ZnO₂).

An upper electrode Cst2 of a storage capacitor Cst may be located on the second gate insulating layer 103. The upper electrode Cst2 may overlap the gate electrode G1 that is located below the upper electrode Cst2. In this case, the gate electrode G1 and the upper electrode Cst2 overlapping each other with the second gate insulating layer 103 therebetween may constitute the storage capacitor Cst. That is, the gate electrode G1 may function as a lower electrode Cst1 of the storage capacitor Cst.

As such, the storage capacitor Cst and the thin-film transistor TFT may overlap each other. In some embodiments, the storage capacitor Cst may not overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single layer or multi-layer structure including the above material.

The interlayer insulating layer 105 may cover the upper electrode Cst2. The interlayer insulating layer 105 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). ZnOₓ may include zinc oxide (ZnO) and/or zinc peroxide (ZnO₂). The interlayer insulating layer 105 may have a single layer or multi-layer structure including the above inorganic insulating material.

Each of a drain electrode D1 and a source electrode S1 may be located on the interlayer insulating layer 105. Each of the drain electrode D1 and the source electrode S1 may include a material having high conductivity. Each of the drain electrode D1 and the source electrode S1 may include a conductive material including molybdenum (Mo), aluminum (Al), copper (Cu), or titanium (Ti), and may have a single layer or multi-layer structure including the above material. In one or more embodiments, each of the drain electrode D1 and the source electrode S1 may have a multi-layer structure including Ti/Al/Ti.

The planarization layer 107 may include an organic insulating material. The planarization layer 107 may include an organic insulating material such as a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

The display element layer DEL is located on the pixel circuit layer PCL having the above structure. The display element layer DEL may include an organic light-emitting diode (OLED) 300, and a pixel electrode 310 of the organic light-emitting diode 300 may be connected (e.g., electrically connected) to the thin-film transistor TFT through a contact hole of the planarization layer 107.

The pixel PX may include the organic light-emitting diode 300 and the thin-film transistor TFT. Each pixel PX may emit, for example, red light, green light, or blue light, or may emit red light, green light, blue light, or white light, through the organic light-emitting diode 300.

The pixel electrode 310 may include a conductive oxide such as indium tin oxide (ITO), indium zinc oxide (IZO), zinc oxide (ZnO₂), indium oxide (In₂O₃), indium gallium oxide (IGO), or aluminum zinc oxide (AZO). In one or more embodiments, the pixel electrode 310 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In one or more embodiments, the pixel electrode 310 may further include a film formed of ITO, IZO, ZnO, or In₂O₃ over/under the reflective film.

A pixel-defining film 112 having an opening portion 112OP through which a central portion of the pixel electrode 310 is exposed is located on the pixel electrode 310 and/or the planarization layer 107. The pixel-defining film 112 may include an organic insulating material and/or an inorganic insulating material. The opening portion 112OP may define an emission area EA of light emitted by the organic light-emitting diode 300. For example, a width of the opening portion 112OP may correspond to a width of the emission area EA.

An intermediate layer 320 including an organic emission layer or a quantum dot emission layer may be located in the opening portion 112OP of the pixel-defining film 112. The intermediate layer 320 may include a high molecular weight organic material or a low molecular weight organic material emitting light of a certain color. The intermediate layer 320 may be formed by ejecting a droplet with an apparatus for manufacturing a display apparatus according to one or more embodiments.

In one or more embodiments, a first functional layer and a second functional layer may be respectively located under and over the organic emission layer of the intermediate layer 320. The first functional layer may include, for example, a hole transport layer (HTL) and/or a hole injection layer (HIL). The second functional layer that is located over the intermediate layer 320 is optional. The second functional layer may include an electron transport layer (ETL) and/or an electron injection layer (EIL). The first functional layer and/or the second functional layer may be a common layer entirely covering the substrate 100, like a common electrode 330 described below.

When the intermediate layer 320 includes the quantum dot emission layer, the quantum dot emission layer may include quantum dots each having a core/shell structure. A core of the quantum dot may be selected from among a group II-VI compound, a group III-V compound, a group IV-VI compound, a group IV element, a group IV compound, and a combination thereof.

The group II-VI compound may be selected from among a binary compound selected from the group consisting of CdSe, CdTe, ZnS, ZnSe, ZnTe, ZnO, HgS, HgSe, HgTe, MgSe, MgS, and a mixture thereof; a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-V compound may be selected from among a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InPSb, GaAlNP, and a mixture thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

The group IV-VI compound may be selected from among a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof. The group IV element may be selected from the group consisting of silicon (Si), germanium (Ge), and a mixture thereof. The group IV compound may be a binary compound selected from the group consisting of SiC, SiGe, and a mixture thereof.

In this case, the binary compound, the ternary compound, or the quaternary compound may exist in particles at a uniform concentration, or may exist in the same particle divided into two states where concentration distributions are partially different. Also, the quantum dot may have a core/shell structure in which one quantum dot surrounds another quantum dot. An interface between the core and the shell may have a concentration gradient in which a concentration of an element in the shell gradually decreases toward the center.

In some embodiments, a quantum dot may have a core-shell structure including a core including a nanocrystal and a shell surrounding the core. The shell of the quantum dot may function as a protective layer for maintaining semiconductor characteristics by preventing or reducing chemical denaturation of the core and/or a charging layer for giving electrophoretic characteristics to the quantum dot. The shell may have a single layer or multi-layer structure. An interface between the core and the shell may have a concentration gradient in which a concentration of an element in the shell gradually decreases toward the center. Examples of the shell of the quantum dot may include an oxide of a metal or a non-metal, a semiconductor compound, and a combination thereof.

Examples of the oxide of the metal or the non-metal may include, but are not limited to, a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO and a ternary compound such as MgAl₂O₄, CoFe₂O₄, NiFe₂O₄, or CoMn₂O₄.

Examples of the semiconductor compound may include, but are not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb.

A quantum dot may have a full width at half maximum (FWHM) of an emission wavelength spectrum of about 45 nm or less, preferably about 40 nm or less, and more preferably about 30 nm or less. In this range, color purity or color reproducibility may be improved. Also, because light emitted through the quantum dot is emitted in all directions, an optical viewing angle may be improved.

Also, a quantum dot may have a shape that is generally used in the art but is not particularly limited thereto. More specifically, a quantum dot may be a spherical, pyramid, multi-arm, or cubic-shaped nano particle, nano-tube, nano-wire, nano-fiber, or nano-plate particle.

A color of light emitted from the quantum dot may be controlled according to a particle size, and thus the quantum dot may have any of various suitable emission colors such as blue, red, or green.

In one or more embodiments, a hole layer may be located on a top surface of the quantum dot emission layer. The hole layer may include a hole transport layer and/or a hole injection layer. In this case, the hole layer may include an organic material or an inorganic material. In some embodiments, the hole layer may include any one of CBP, α-NPD, TCTA, and DNTPD. In one or more embodiments, the hole layer may include NiO or MoO₃.

Also, an inorganic electron layer may be located between the pixel electrode 310 and the top surface of the quantum dot emission layer. The inorganic electron layer may include a metal oxide, and a metal may include an alkaline earth metal, a transition metal, a group 13 metal, and/or a group 14 metal. For example, the metal of the metal oxide may include Zn, Ti, Zr, Sn, W, Ta, Ni, Mo, Cu, Mg, Co, Mn, Y, Al, or a combination thereof.

The quantum dot emission layer may include particles. For example, the particles may include scatterers. In this case, the scatterers may include TiO₂.

The common electrode 330 may be formed of a conductive material having a low work function. For example, the common electrode 330 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the common electrode 330 may further include a layer formed of ITO, IZO, ZnO, or In₂O₃ on the (semi)transparent layer including the above material.

In one or more embodiments, the thin-film encapsulation layer 500 may include at least one inorganic encapsulation layer and at least one organic encapsulation layer. According to one or more embodiments, in FIG. 2, the thin-film encapsulation layer 500 includes a first inorganic encapsulation layer 510, an organic encapsulation layer 520, and a second inorganic encapsulation layer 530 that are sequentially stacked.

Each of the first and second inorganic encapsulation layers 510 and 530 may include at least one inorganic material from among aluminum oxide, titanium oxide, tantalum oxide, hafnium oxide, zinc oxide, silicon oxide, silicon nitride, and/or silicon oxynitride. The organic encapsulation layer 520 may include a polymer-based material. Examples of the polymer-based material may include an acrylic resin, an epoxy resin, polyimide, and polyethylene. In one or more embodiments, the organic encapsulation layer 520 may include acrylate.

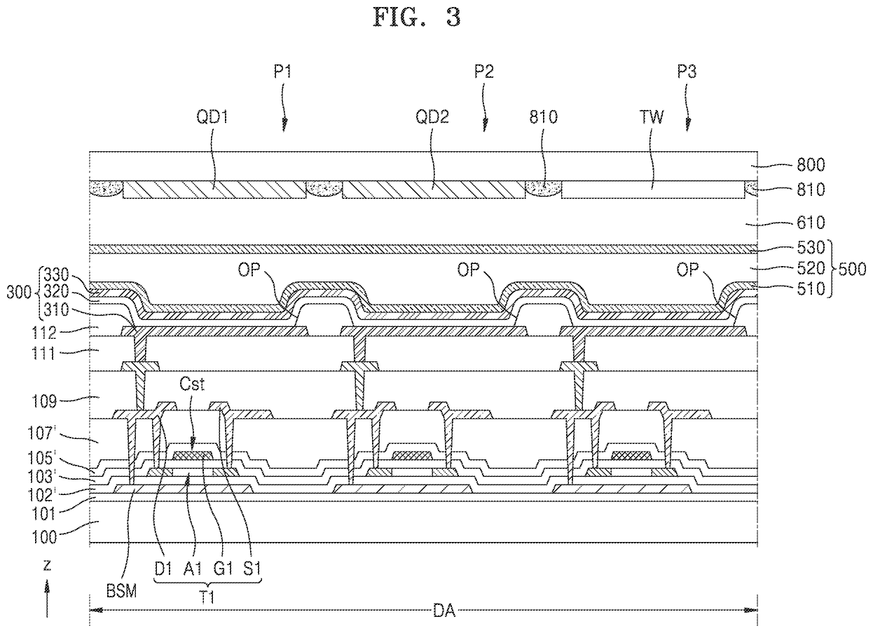

In one or more embodiments, the thin-film encapsulation layer 500 may have a structure in which the substrate 100 and an upper substrate 800 (see, e.g., FIG. 3) that is a transparent member are coupled to each other by a sealing member to seal an inner space between the substrate 100 and the upper substrate 800. In this case, a moisture absorbent or a filler 610 (see FIG. 3) may be located in the inner space. The sealing member may be a sealant, and in one or more embodiments, the sealing member may include a material cured by a laser. For example, the sealing member may be a frit. Specifically, the sealing member may include a urethane resin, an epoxy resin, or an acrylic resin that is an organic sealant, or silicone that is an inorganic sealant. Examples of the urethane resin may include urethane acrylate. Examples of the acrylic resin may include butyl acrylate and ethylhexyl acrylate. The sealing member may include a material that is cured by heat.

A touch electrode layer including touch electrodes may be located on the thin-film encapsulation layer 500, and an optical functional layer may be located on the touch electrode layer. The touch electrode layer may obtain coordinate information according to an external input, for example, a touch event. The optical functional layer may reduce a reflectance of light (e.g., external light) incident on the display apparatus 1, and/or improve color purity of light emitted from the display apparatus 1. For example, the optical functional layer may include a phase retarder and a polarizer. The phase retarder may be of a film type or a liquid crystal coating type, and may include a λ/2 phase retarder and/or a λ/4 phase retarder. The polarizer may also be of a film type or a liquid crystal coating type. The film type polarizer may include a stretchable synthetic resin film, and the liquid crystal coating type polarizer may include liquid crystals arranged in a certain arrangement. The phase retarder and the polarizer may further include a protective film.

In one or more embodiments, the optical functional layer may include a black matrix and color filters. The color filters may be arranged in consideration of a color of light emitted by each of pixels PX of the display apparatus 1. Each of the color filters may include a red, green, or blue pigment or dye. Alternatively, each of the color filters may further include quantum dots in addition to the pigment or dye. Alternatively, some of the color filters may not include the pigment or dye, and may include particles (e.g., scatterers) such as titanium oxide. The color filters may be formed by ejecting a droplet by using an apparatus for manufacturing a display apparatus according to one or more embodiments.

In one or more embodiments, the optical functional layer may have a destructive interference structure. The destructive interference structure may include a first reflective layer and a second reflective layer that are located on or at different layers. First reflected light and second reflected light respectively reflected by the first reflective layer and the second reflective layer may destructively interfere with each other, thereby reducing a reflectance of external light.

An adhesive member may be located between the touch electrode layer and the optical functional layer. The adhesive member may be any suitable adhesive member without limitation. For example, the adhesive member may be a pressure sensitive adhesive (PSA).

FIG. 3 is a cross-sectional view illustrating a part of a display apparatus, according to one or more embodiments.

Referring to FIG. 3, a display apparatus may include the display area DA and a non-display area. In this case, the non-display area is the same as or similar to that of FIGS. 1 and 2, and thus the following will focus on a difference in the display area DA.

The display apparatus may include a buffer layer 101 and an additional buffer layer 102′. In this case, each of the buffer layer 101 and the additional buffer layer 102′ may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). ZnOₓ may include zinc oxide (ZnO) and/or zinc peroxide (ZnO₂).

A bias electrode BSM may be located between the buffer layer 101 and the additional buffer layer 102′ to correspond to a thin-film transistor T1. That is, the bias electrode BSM may overlap the semiconductor layer A1 of the thin-film transistor T1. A voltage may be applied to the bias electrode BSM. The bias electrode BSM may prevent or substantially prevent external light from reaching the semiconductor layer A1. Accordingly, characteristics of the thin-film transistor T1 may be stabilized. The bias electrode BSM may be omitted when desired.

The thin-film transistor T1 includes the semiconductor layer A1, the gate electrode G1, the source electrode S1, and the drain electrode D1. In this case, the semiconductor layer A1 may include amorphous silicon or polysilicon. In one or more embodiments, the semiconductor layer A1 may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In some embodiments, the semiconductor layer A1 may be formed of a Zn oxide-based material such as Zn oxide, In—Zn oxide, or Ga—In—Zn oxide. In one or more embodiments, the semiconductor layer A1 may be formed of an In—Ga—Zn—O (IGZO), In—Sn—Zn—O (ITZO), or In—Ga—Sn—Zn—O (IGTZO) semiconductor containing a metal such as indium (In), gallium (Ga), or tin (Sn) in ZnO. The semiconductor layer A1 may include a channel region, and a source region and a drain region located on or at opposite sides of the channel region. Also, the semiconductor layer A1 may have a single layer or multi-layer structure.

A first gate insulating layer 103′, the gate electrode G1, a second gate insulating layer 105′, an interlayer insulating layer 107′, a first planarization layer 109, and a second planarization layer 111 may be sequentially stacked on the semiconductor layer A1. In this case, the first gate insulating layer 103′, the second gate insulating layer 105′, and the interlayer insulating layer 107′ may be respectively the same as the first gate insulating layer 102, the second gate insulating layer 103, and the interlayer insulating layer 105 of FIG. 2, and the first planarization layer 109 and the second planarization layer 111 may be the same as the planarization layer 107 of FIG. 2.

The gate electrode G1 is located on the first gate insulating layer 103′ to at least partially overlap the semiconductor layer A1. The gate electrode G1 may include molybdenum (Mo), aluminum (Al), copper (Cu), or titanium (Ti), and may have a single layer or multi-layer structure. A lower electrode of the storage capacitor Cst may be located on the same layer as the gate electrode G1. The lower electrode may be formed of the same material as that of the gate electrode G1.

Also, the organic light-emitting diode 300 may be located on the second planarization layer 111. The organic light-emitting diode 300 may form a plurality of pixels (e.g., first through third pixels P1, P2, and P3). In this case, the intermediate layer 320 of the organic light-emitting diode 300 located in each of the first through third pixels P1, P2, and P3 may be commonly provided. Accordingly, the organic light-emitting diode 300 included in each of the first through third pixels P1, P2, and P3 may emit light of the same color. For example, the intermediate layer 320 may include an organic emission layer including a fluorescent or phosphorescent material for emitting blue light. Functional layers such as a hole transport layer (HTL), a hole injection layer (HIL), an electron transport layer (ETL), and an electron injection layer (EIL) may be selectively further provided under and over the organic emission layer.

The pixel-defining film 112 may be located on the pixel electrode 310 of the organic light-emitting diode 300. Also, the intermediate layer 320 and the common electrode 330 may be located at each of the first through third pixels P1, P2, and P3 and the pixel-defining film 112 over the entire display area DA.

The thin-film encapsulation layer 500 may be located on the organic light-emitting diode 300. In this case, the thin-film encapsulation layer 500 may include the first inorganic encapsulation layer 510, the organic encapsulation layer 520, and the second inorganic encapsulation layer 530.

An optical functional member facing the substrate 100 may be located on the thin-film encapsulation layer 500. In this case, the optical functional member may include an upper substrate 800 facing the substrate 100, and color conversion layers (e.g., first and second color conversion layers QD1 and QD2), a transmissive layer TW and light-blocking patterns 810 located on the upper substrate 800. In this case, each of the first and second color conversion layers QD1 and QD2 and the transmissive layer TW may form one emission area.

The first and second color conversion layers QD1 and QD2 may be layers that transmit or express (e.g., clearly express) a color of light emitted from the organic light-emitting diode 300 or convert a color into another color. Each of the first and second color conversion layers QD1 and QD2 may include quantum dots, and may include a quantum conversion layer. A quantum dot is a semiconductor particle having a diameter of 2 nm to 10 nm and having unusual electrical and optical properties. When a quantum dot is exposed to light, the quantum dot may emit light of a specific frequency according to a particle size and a type of a material. For example, when a quantum dot is exposed to light, the quantum dot may emit red light, green light, or blue light according to a particle size and/or a type of a material.

A core of a quantum dot may be selected from among a group II-VI compound, a group III-V compound, a group IV-VI compound, a group IV element, a group IV compound, and a combination thereof.

The group II-VI compound may be selected from among a binary compound selected from the group consisting of CdSe, CdTe, ZnS, ZnSe, ZnTe, ZnO, HgS, HgSe, HgTe, MgSe, MgS, and a mixture thereof; a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-V compound may be selected from among a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InPSb, GaAlNP, and a mixture thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

The group IV-VI compound may be selected from among a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof. The group IV element may be selected from the group consisting of silicon (Si), germanium (Ge), and a mixture thereof. The group IV compound may be a binary compound selected from the group consisting of SiC, SiGe, and a mixture thereof.

In this case, the binary compound, the ternary compound, or the quaternary compound may exist in particles at a uniform concentration, or may exist in the same particle divided into two states where concentration distributions are partially different. Also, the quantum dot may have a core/shell structure in which one quantum dot surrounds another quantum dot. An interface between the core and the shell may have a concentration gradient in which a concentration of an element in the shell gradually decreases toward the center.

In some embodiments, a quantum dot may have a core shell structure including a core including a nanocrystal and a shell surrounding the core. The shell of the quantum dot may function as a protective layer for maintaining semiconductor characteristics by preventing or reducing chemical denaturation of the core and/or a charging layer for giving electrophoretic characteristics to the quantum dot. The shell may have a single layer or multi-layer structure. An interface between the core and the shell may have a concentration gradient in which a concentration of an element in the shell gradually decreases toward the center. Examples of the shell of the quantum dot may include an oxide of a metal or a non-metal, a semiconductor compound, and a combination thereof.

Examples of the oxide of the metal or the non-metal may include, but are not limited to, a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO and a ternary compound such as MgAl₂O₄, CoFe₂O₄, NiFe₂O₄, or CoMn₂O₄.

Examples of the semiconductor compound may include, but are not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb.

A quantum dot may have a full width at half maximum (FWHM) of an emission wavelength spectrum of about 45 nm or less, preferably about 40 nm or less, and more preferably about 30 nm or less. In this range, color purity or color reproducibility may be improved. Also, because light emitted through the quantum dot is emitted in all directions, an optical viewing angle may be improved.

Also, a quantum dot may have a shape that is generally used in the art but is not particularly limited thereto. More specifically, a quantum dot may be a spherical, pyramid, multi-arm, or cubic-shaped nano particle, nano-tube, nano-wire, nano-fiber, or nano-plate particle.

Each of the first and second color conversion layers QD1 and QD2 may be located to at least partially correspond to an emission area defined by the opening portion OP of the pixel-defining film 112. For example, the first color conversion layer QD1 may be located to correspond to an emission area of the first pixel P1, and the second color conversion layer QD2 may be located to correspond to an emission area of the second pixel P2. The transmissive layer TW, not a color conversion layer, may be located to correspond to an emission area of the third pixel P3. The transmissive layer TW may be formed of an organic material for emitting light without changing a wavelength of light emitted from the organic light-emitting diode 300 of the third pixel P3. However, the disclosure is not limited thereto. A color conversion layer may also be located in the emission area of the third pixel P3.

Particles may be distributed in the first and second color conversion layers QD1 and QD2 and the transmissive layer TW. Accordingly, color spreadability may be uniform. In this case, the particles may include scatterers. For example, the scatterers may include TiO₂.

The light-blocking pattern 810 may be located between the first and second color conversion layers QD1 and QD2 and the transmissive layer TW. The light-blocking pattern 810 that is a black matrix may be a member for improving color sharpness and contrast. The light-blocking pattern 810 may be located between emission areas of the first through third pixels P1, P2, and P3. Because the light-blocking pattern 810 may be a black matrix for absorbing visible light, color mixing of light emitted by emission areas of neighboring pixels may be prevented or reduced and visibility and contrast may be improved.

In some embodiments, all of a plurality of organic light-emitting diodes 300 may emit blue light. In this case, the first color conversion layer QD1 may include quantum dots emitting red light, and the second color conversion layer QD2 may include quantum dots emitting green light. Accordingly, light emitted to the outside of the display apparatus may be red light, green light, and blue light, and any of various suitable colors may be reproduced through combinations.

A filler 610 may be further located between the substrate 100 and the upper substrate 800. The filler 610 may function as a buffer against external pressure, and the like. The filler 610 may include an organic material such as methyl silicone, phenyl silicone, or polyimide. However, the disclosure is not limited thereto, and the filler 610 may include an organic sealant such as a urethane resin, an epoxy resin, or an acrylic resin, or an inorganic sealant such as silicone.

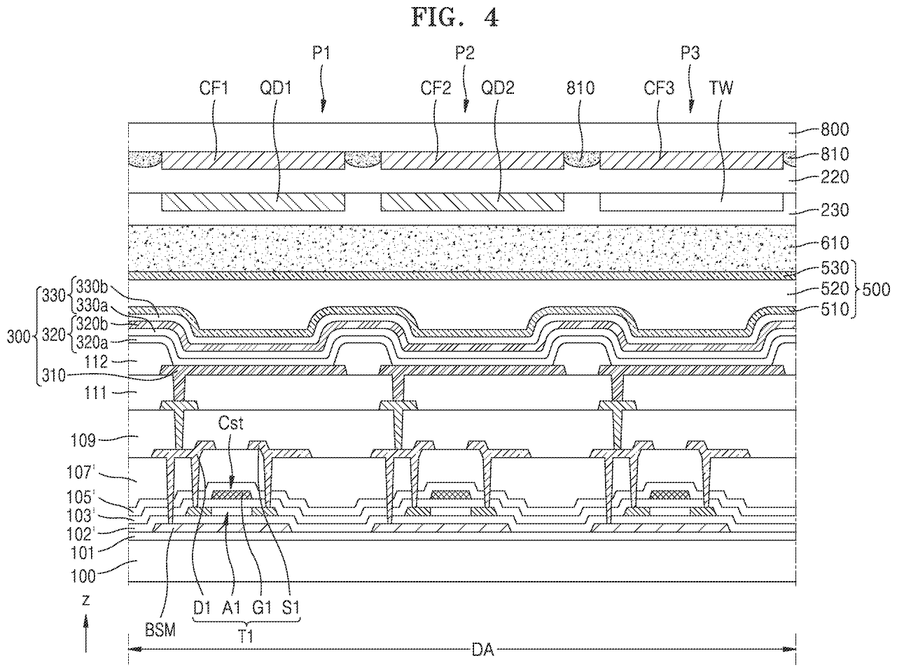

FIG. 4 is a cross-sectional view illustrating a part of a display apparatus, according to one or more embodiments.

Referring to FIG. 4, the display apparatus may be similar to a display apparatus of FIG. 3. The following will focus on a difference from the display apparatus of FIG. 3.

The organic light-emitting diodes 300 included in the plurality of pixels (e.g., the first through third pixels P1, P2, and P3), may each be formed by stacking a plurality of intermediate layers (e.g., first and second intermediate layers 320a and 320b), and a plurality of common electrodes (e.g., first and second common electrodes 330a and 330b).

For example, the organic light-emitting diode 300 may be formed by sequentially stacking the first intermediate layer 320a, the first common electrode 330a, the second intermediate layer 320b, and the second common electrode 330b on the pixel electrode 310. Each of the first intermediate layer 320a and the second intermediate layer 320b may include an organic emission layer including a fluorescent or phosphorescent material for emitting red, green, blue, or white light. The organic emission layer may be formed of a low molecular weight organic material or a high molecular weight organic material, and functional layers such as a hole transport layer (HTL), a hole injection layer (HIL), an electron transport layer (ETL), and an electron injection layer (EIL) may be selectively located under and over the organic emission layer. In some embodiments, each of the first intermediate layer 320a and the second intermediate layer 320b may include an organic emission layer that emits blue light.

Each of the first common electrode 330a and the second common electrode 330b may be a light-transmitting electrode or a reflective electrode. In some embodiments, the common electrode 330 may be a transparent or semi-transparent electrode and may include a metal thin film having a low work function including lithium (Li), calcium (Ca), LiF/Ca, LiF/Al, aluminum (Al), silver (Ag), magnesium (Mg), or a compound thereof. Also, a transparent conductive oxide (TCO) film including ITO, IZO, ZnO, or In₂O₃ may be further located on the metal thin film. The first common electrode 330a may be a floating electrode.

The first intermediate layer 320a, the second intermediate layer 320b, the first common electrode 330a, and the second common electrode 330b may be integrally formed over a plurality of pixels.

In the present embodiment, color filters (e.g., first through third color filters CF1, CF2, and CF3), may be provided on the upper substrate 800. The first through third color filters CF1, CF2, and CF3 may be introduced to display a full color image, improve color purity, and improve outdoor visibility.

The first through third color filters CF1, CF2, and CF3 may be located on the upper substrate 800 to respectively correspond to the first through third pixels P1, P2, and P3. The light-blocking pattern 810 may be located between the first through third color filters CF1, CF2, and CF3.

A protective layer 220 may cover the light-blocking patterns 810 and the first through third color filters CF1, CF2, and CF3. The protective layer 220 may include an inorganic material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc Oxide (ZnOₓ) may be zinc oxide (ZnO) and/or perzinc oxide (ZnO₂). The protective layer 220 may include an organic material such as polyimide or epoxy.

The first color conversion layer QD1, the second color conversion layer QD2, and the transmissive layer TW may respectively overlap the first color filter CF1, the second color filter CF2, and the third color filter CF3 with the protective layer 220 therebetween. An additional protective layer 230 may be further provided on the upper substrate 800 to cover the first color conversion layer QD1, the second color conversion layer QD2, and the transmissive layer TW. The additional protective layer 230 may be formed of an organic material or an inorganic material.

The first color conversion layer QD1 and the second color conversion layer QD2 may include quantum dots that emit light of different colors. For example, the first color conversion layer QD1 may emit red light, and the second color conversion layer QD2 may emit green light. Also, the transmissive layer TW may transmit therethrough blue light emitted by the organic light-emitting diode 300 of the third pixel P3.

In this case, the first color filter CF1 may be a red color filter, the second color filter CF2 may be a green color filter, and the third color filter CF3 may be a blue color filter.

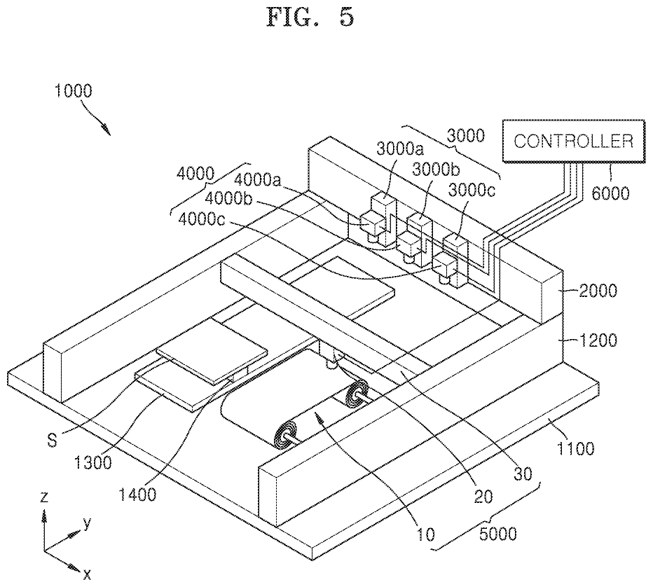

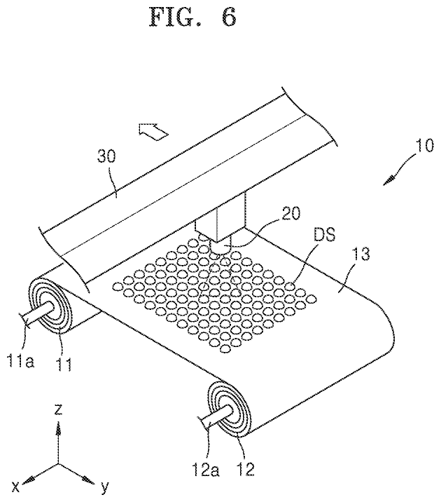

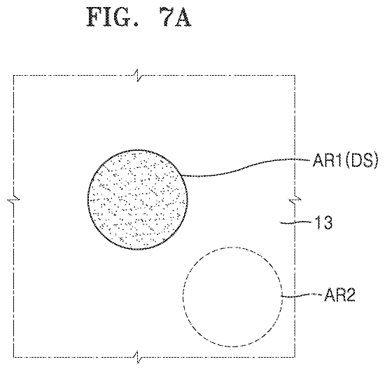

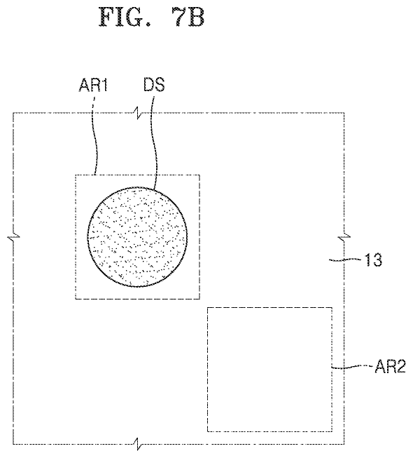

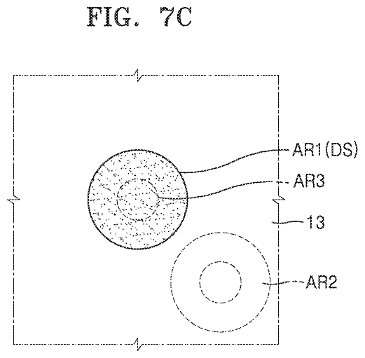

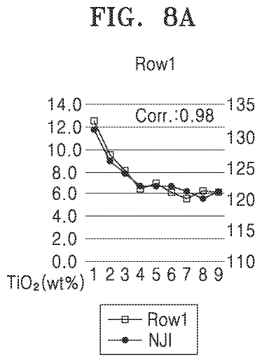

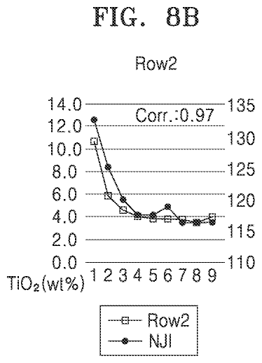

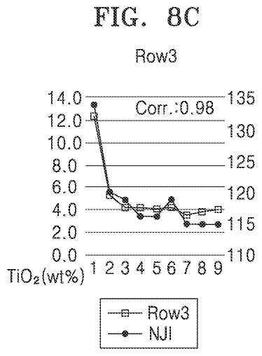

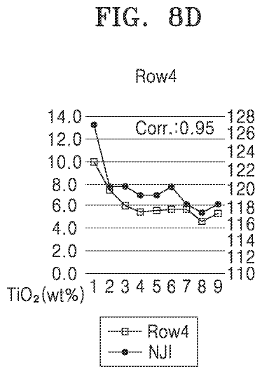

FIG. 5 is a perspective view illustrating an apparatus for manufacturing a display apparatus, according to one or more embodiments. FIG. 6 is a perspective view illustrating a test table of FIG. 5. FIGS. 7A through 7C are plan views illustrating a part of a test member of FIG. 6. FIG. 8A through FIG. 8D are graphs illustrating a relationship between a particle concentration and a correction luminance.

Referring to FIGS. 5 through 8D, an apparatus 1000 for manufacturing a display apparatus may include a stage 1100, a first gantry 2000, a moving unit 3000, a droplet ejector 4000, a droplet measurer 5000, and a controller 6000.

The stage 1100 may include guide members 1200 and a substrate moving member 1300. The stage 1100 may include an alignment mark for aligning a display substrate S.

The display substrate S may be a display apparatus to be manufactured. For example, the display substrate S may be a display apparatus to be manufactured including layers from the substrate 100 to the pixel-defining film 112 of FIGS. 2 through 4. In this case, the apparatus 1000 may form an organic emission layer including particles on the display substrate S. In one or more embodiments, the display substrate S may be a display apparatus to be manufactured including the upper substrate 800 and the light-blocking patterns 810 of FIG. 3 or including the upper substrate 800, the light-blocking patterns 810, the first through third color filters CF1, CF2, and CF3, and the protective layer 220 of FIG. 4. In this case, the apparatus 1000 may arrange the first and second color conversion layers QD1 and QD2 including particles between the light-blocking patterns 810 on the display substrate S. In one or more embodiments, the display substrate S may be a display apparatus to be manufactured including the upper substrate 800 and the light-blocking patterns 810 of FIG. 4. In this case, the apparatus 1000 may form the first through third color filters CF1, CF2, and CF3 including particles on the upper substrate 800. For convenience of explanation, the following will be described in more detail assuming that the display substrate S is a display apparatus to be manufactured including the upper substrate 800 and the light-blocking patterns 810, and the first and second color conversion layers QD1 and QD2 are formed on the display substrate S.

The guide members 1200 may be spaced from each other (e.g., spaced from each other in the x direction of FIG. 5) with the substrate moving member 1300 therebetween. A length of each of the guide members 1200 may be greater than a length of an edge of the display substrate S. In this case, the length of the guide member 1200 and the length of the edge of the display substrate S may be measured in the y direction of FIG. 5.

The first gantry 2000 may be located on the guide member 1200. In one or more embodiments, the guide member 1200 may include a rail through which the first gantry 2000 moves (e.g., linearly moves) in a longitudinal direction of the guide member 1200. In one or more embodiments, the guide member 1200 may include a linear motion rail.

The substrate moving member 1300 may be located on the stage 1100, and may include a substrate rotating member 1400. The substrate moving member 1300 may extend in the longitudinal direction of the guide member 1200. For example, referring to FIG. 5, the substrate moving member 1300 may extend in the y direction. In other words, the longitudinal direction may be the y direction as shown in FIG. 5. Also, the substrate moving member 1300 may include a rail through which the substrate rotating member 1400 moves (e.g., linearly moves). In one or more embodiments, the substrate moving member 1300 may include a linear motion rail.

The substrate rotating member 1400 may rotate on the substrate moving member 1300. When the substrate rotating member 1400 rotates, the display substrate S located on the substrate rotating member 1400 may rotate. In one or more embodiments, the substrate rotating member 1400 may rotate about a rotation axis perpendicular to a surface of the stage 1100 on which the display substrate S is mounted. When the substrate rotating member 1400 rotates about the rotation axis perpendicular to the surface of the stage 1100 on which the display substrate S is mounted, the display substrate S located on the substrate rotating member 1400 may also rotate about the rotation axis perpendicular to the surface of the stage 1100 on which the display substrate S is mounted.

The first gantry 2000 may be located on the guide member 1200. That is, the first gantry 2000 may be located on the guide members 1200 that are spaced from each other with the substrate moving member 1300 therebetween.

The first gantry 2000 may move in the longitudinal direction of the guide member 1200. In one or more embodiments, the first gantry 2000 may manually linearly move, or may include a motor cylinder or the like and may automatically linearly move. For example, the first gantry 2000 may include a linear motion block moving along a linear motion rail and may automatically linearly move.

The moving unit 3000 and the droplet ejector 4000 for ejecting the droplet DS may be located on the first gantry 2000. In one or more embodiments, the moving unit 3000 may move (e.g., linearly move) on the first gantry 2000. For example, the first gantry 2000 may include a rail through which the moving unit 3000 linearly moves.

The moving unit 3000 may include at least one nozzle moving unit, and at least one ejector of the droplet ejector 4000 may be arranged in various suitable ways. In this case, the moving unit 3000 may move (e.g., linearly move) on the first gantry 2000, and the droplet ejector 4000 may be located on the moving unit 3000 and may supply the droplet DS to the display substrate S. For example, one nozzle moving unit and one ejector may be provided. In this case, the ejector may include one or more nozzle heads for ejecting the droplet DS.

Alternatively, one or more ejectors may be provided, and one nozzle moving unit may be provided. In this case, when a plurality of ejectors is provided, the plurality of ejectors may be located on one nozzle moving unit and may concurrently (e.g., simultaneously) move as the nozzle moving unit moves.

Alternatively, a plurality of nozzle moving units and a plurality of ejectors may be provided. In this case, at least one ejector may be located on one nozzle moving unit. For convenience of explanation, the following will be described in more detail assuming that one ejector is located on one nozzle moving unit.

The moving unit 3000 may include a plurality of nozzle moving units. In one or more embodiments, the moving unit 3000 may include a first nozzle moving unit 3000a, a second nozzle moving unit 3000b, and a third nozzle moving unit 3000c. In one or more embodiments, the moving unit 3000 may include at least one nozzle moving unit, or may include four or more nozzle moving units. However, for convenience of explanation, the following will be described in more detail assuming that the moving unit 3000 includes the first nozzle moving unit 3000a, the second nozzle moving unit 3000b, and the third nozzle moving unit 3000c.

In one or more embodiments, an interval between the first nozzle moving unit 3000a and the second nozzle moving unit 3000b may be the same as an interval between the second nozzle moving unit 3000b and the third nozzle moving unit 3000c. The second nozzle moving unit 3000b may be between the first nozzle moving unit 3000a and the third nozzle moving unit 3000c. In one or more embodiments, an interval between the first nozzle moving unit 3000a and the second nozzle moving unit 3000b may be different from an interval between the second nozzle moving unit 3000b and the third nozzle moving unit 3000c.

The moving unit 3000 may move (e.g., linearly move) on the first gantry 2000. In more detail, the moving unit 3000 may move in a longitudinal direction of the first gantry 2000. For example, at least one of the first nozzle moving unit 3000a, the second nozzle moving unit 3000b, or the third nozzle moving unit 3000c may move in the x direction or the −x direction as shown in FIG. 5.

In one or more embodiments, the moving unit 3000 may manually linearly move. In one or more embodiments, the moving unit 3000 may include a motor cylinder or the like and may automatically linearly move. For example, the moving unit 3000 may include a linear motion block that moves along a linear motion rail.

An ejector of the droplet ejector 4000 may be located on a nozzle moving unit of the moving unit 3000. In this case, the ejector of the droplet ejector 4000 may supply the droplet DS to the display substrate S. In this case, the ejector of the droplet ejector 4000 may supply various suitable materials to the display substrate S. For example, a first ejector 4000a may be located on the first nozzle moving unit 3000a. As another example, a second ejector 4000b may be located on the second nozzle moving unit 3000b. As another example, a third ejector 4000c may be located on the third nozzle moving unit 3000c.

In this case, at least one of the first ejector 4000a through the third ejector 4000c may include at least one ejection hole for ejecting the droplet DS. For convenience of explanation, the following will be described in more detail assuming that each of the first ejector 4000a through the third ejector 4000c includes one ejection hole.

The droplet ejector 4000 may eject the droplet DS to the display substrate S or a test table 10. In this case, the droplet DS may be red, green, or blue ink in which pigment particles (e.g., particles) are mixed in a solvent, an alignment solution including particles, or a liquid crystal including particles. In one or more embodiments, the droplet DS may be a high molecular weight organic material or a low molecular weight organic material corresponding to an organic emission layer of an organic light-emitting display apparatus including scatterers. In one or more embodiments, the droplet DS may include a color conversion layer material including particles or a color filter material including particles. In one or more embodiments, the droplet DS may include quantum dots and particles. For convenience of explanation, the following will be described in more detail assuming that the droplet DS includes particles and quantum dots.

An amount of the droplet DS ejected from each of the first ejector 4000a, the second ejector 4000b, and the third ejector 4000c may be independently adjusted. In this case, each of the first ejector 4000a, the second ejector 4000b, and the third ejector 4000c may be connected (e.g., electrically connected) to the controller 6000. Accordingly, an amount of the droplet DS ejected from each of the first ejector 4000a, the second ejector 4000b, and the third ejector 4000c may be adjusted by the controller 6000.

The droplet measurer 5000 may measure the droplet DS ejected by the droplet ejector 4000. In more detail, the droplet measurer 5000 may capture an image of the droplet DS ejected by the droplet ejector 4000 and mounted on the display substrate S.

The droplet measurer 5000 may include the test table 10, a measurer 20, and a second gantry 30.

The test table 10 may be located on the stage 1100. In this case, the test table 10 may be located between the guide members 1200. In the present embodiment, the apparatus 1000 may include at least one test table 10. For example, the apparatus 1000 may include a plurality of test tables 10. Accordingly, the apparatus 1000 may concurrently (e.g., simultaneously) test amounts of the droplet DS ejected by a plurality of ejectors, thereby improving the efficiency of a droplet test.

The test table 10 may include a film feeder 11 and a film collector 12. The film feeder 11 and the film collector 12 may be spaced from each other. In the present embodiment, the film feeder 11 and the film collector 12 may be spaced from each other in the longitudinal direction of the guide member 1200. For example, the film feeder 11 and the film collector 12 may be spaced from each other in the y direction. In this case, the film feeder 11 and the film collector 12 may be fixedly connected to the ground, an inner surface of a building, or the like.

The film feeder 11 may feed a test member 13. In this case, the test member 13 may be a film. The test member 13 may be arranged in a roll form on the film feeder 11. In other words, the test member 13 may be wound around the film feeder 11. The film feeder 11 may include a first shaft 11a, and the first shaft 11a may rotate to feed the test member 13. The first shaft 11a may be connected to a driver. In this case, the driver may include a motor. In one or more embodiments, the driver may include a cylinder and cam structure. In this case, the driver is not limited thereto, and may include any structure and device that is connected to the first shaft 11a and rotates the first shaft 11a. Accordingly, the first shaft 11a may be rotated by the driver.

The film collector 12 may collect the test member 13. In more detail, the film collector 12 may collect the test member 13 fed by the film feeder 11. The test member 13 may be arranged in a roll form on the film collector 12. That is, the test member 13 where the ejected droplet DS has been completely measured may be wound around the film collector 12. The film collector 12 may include a second shaft 12a, and the second shaft 12a may rotate to collect the test member 13. The second shaft 12a may be connected to a driver. In this case, the driver may be the same as or similar to the driver connected to the first shaft 11a. Accordingly, the second shaft 12a may be rotated by the driver.

The test member 13 may be fed by the film feeder 11, and may be collected by the film collector 12. Accordingly, when a test of the droplet DS ejected onto a portion of the test member 13 ends, the film feeder 11 and the film collector 12 may change a position of the test member 13 so that another portion of the test member 13 faces the droplet ejector 4000. The test member 13 may include a material that is the same as or similar to that of the display substrate S. For example, the test member 13 may be a glass film or a film including a polymer resin such as polyethersulfone, polyarylate, polyetherimide, polyethylene naphthalate, polyethylene terephthalate, polyphenylene sulfide, polyimide, polycarbonate, cellulose triacetate (TAC), or cellulose acetate propionate.

Although the test table 10 includes the film feeder 11 and the film collector 12 in the present embodiment, in one or more embodiments, the test table 10 may include a test substrate. In this case, the test substrate may be replaced by a robot arm. The test substrate may include a material that is the same as or similar to that of the display substrate S or the test member 13.

The measurer 20 may capture an image of the droplet DS on the test member 13. The measurer 20 may be connected (e.g., electrically connected) to the controller 6000 and may transmit the captured image to the controller 6000.

The measurer 20 may be a confocal microscope or an interferometric microscope. The confocal microscope is a microscope that is capable of obtaining multiple two-dimensional (2D) images of an object at different depths and reconstructing a three-dimensional (3D) structure of the object based on the 2D images. Examples of the confocal microscope may include a chromatic confocal microscope and a chromatic line confocal microscope. The interferometric microscope is a microscope that observes and quantitatively measures a change in phase and irregularities of a microstructure of an object. Examples of the interferometric microscope may include a laser interferometric microscope and a white light interferometric microscope. In one or more embodiments, the measurer 20 may include a lighting unit, a lens, and a camera. In this case, the measurer 20 may be located in the order of the lighting unit, the lens, and the camera from a portion close to the droplet DS. The measurer 20 is not limited thereto, and may include any suitable device and structure capable of capturing an image of the droplet DS on the test member 13. For convenience of explanation, the following will be described in more detail assuming that the measurer 20 includes the lighting unit, the lens, and the camera.

The droplet measurer 5000 may include at least one measurer 20. For example, the droplet measurer 5000 may include a plurality of measurers 20. Accordingly, the droplet measurer 5000 may concurrently (e.g., simultaneously) test amounts of the droplet DS ejected by a plurality of ejectors, thereby improving the efficiency of a droplet test.

The measurer 20 may move (e.g., linearly move) along the second gantry 30, and may move (e.g., linearly move) along with the second gantry 30. In more detail, the measurer 20 may move in a longitudinal direction of the second gantry 30. For example, the measurer 20 may move in the x direction or the −x direction of FIG. 5. Also, the measurer 20 may move (e.g., linearly move) along with the second gantry 30 as the second gantry 30 moves. For example, the measurer 20 may move in the y direction or the −y direction of FIG. 5 along with the second gantry 30.

The second gantry 30 may be located on the guide member 1200. That is, the second gantry 30, similar to the first gantry 2000, may be located on the guide members 1200 that are spaced from each other with the test table 10 therebetween.

The second gantry 30 may move in the longitudinal direction of the guide member 1200. In one or more embodiments, the second gantry 30 may manually linearly move, or may include a motor cylinder or the like and may automatically linearly move. For example, the second gantry 30 may include a linear motion block that moves along a linear motion rail and may automatically linearly move.

Although the measurer 20 is connected to the second gantry 30, in one or more embodiments, the first gantry 2000 and the second gantry 30 may be integrally provided. In this case, the measurer 20 may be spaced from the moving unit 3000, or may be located on the moving unit 3000 like the droplet ejector 4000. However, for convenience of explanation, the following will be described in more detail assuming that the apparatus 1000 includes the second gantry 30, and the measurer 20 is connected to the second gantry 30.

The controller 6000 may calculate a luminance of the droplet DS by using an image of the droplet DS captured by the measurer 20. Also, the controller 6000 may calculate a concentration of particles contained in the droplet DS based on the calculated luminance of the droplet DS. In one or more embodiments, the controller 6000 may calculate a luminance of the droplet DS after dividing a luminance of the droplet DS whose image is captured by a luminance of a portion of the test member 13 where the droplet DS does not exist (i.e., where the droplet DS is not present) or after adjusting a luminance of the entire image, and may calculate a concentration of particles contained in the droplet DS based on the calculated luminance of the droplet DS. In this case, the controller 6000 may average a luminance of the droplet DS whose image is captured over an entire surface of the droplet DS, and may calculate a concentration of particles contained in the droplet DS based on an obtained average value. Alternatively, the controller 6000 may calculate a luminance of a remaining portion of the droplet DS except for an area of an image of the droplet DS where reflection occurs, and then may calculate a concentration of particles contained in the droplet DS based on the calculated luminance of the remaining portion. Alternatively, the controller 6000 may average a luminance of a certain area including a planar shape (or a planar area) of the droplet DS, and may calculate a concentration of particles contained in the droplet DS based on an obtained average value.

An operation of the apparatus 1000, a method of measuring a droplet by using the apparatus 1000, and a method of manufacturing a display apparatus by using the apparatus 1000 will now be described in more detail.

The apparatus 1000 may measure a concentration of particles contained in the droplet DS as described above.

In more detail, the first gantry 2000 may move (e.g., linearly move) on the guide members 1200 so that the first ejector 4000a, the second ejector 4000b, and the third ejector 4000c correspond to a position at which the test member 13 is located. Also, the first nozzle moving unit 3000a, the second nozzle moving unit 3000b, and the third nozzle moving unit 3000c may move (e.g., linearly move) on the first gantry 2000 so that the first ejector 4000a, the second ejector 4000b, and the third ejector 4000c are located to correspond to the test member 13. Next, the first ejector 4000a, the second ejector 4000b, and the third ejector 4000c may eject the droplet DS onto the test member 13.

When the above process is completed, the second gantry 30 may operate to place the measurer 20 over the droplet DS. The measurer 20 may capture an image of the droplet DS located on the test member 13. In this case, in a state where the lighting unit operates, an image of the droplet DS may be captured. The image of the droplet DS may be transmitted from the measurer 20 to the controller 6000.

The controller 6000 may calculate a concentration of particles contained in the droplet DS based on the image of the droplet DS.

In one or more embodiments, referring to FIG. 7A, when an image of the droplet DS is transmitted to the controller 6000, the controller 6000 may define a planar shape of the droplet DS. For example, the controller 6000 may determine an edge of the planar shape of the droplet DS to define the planar shape of the droplet DS.

The controller 6000 may analyze the image and may calculate an average value of luminances (e.g., all luminances) of the planar shape of the droplet DS. In this case, the controller 6000 may calculate luminances of respective portions of the transmitted image. That is, the controller 6000 may use a method of dividing the transmitted image into a plurality of lattice-shaped portions and calculating luminances of the lattice-shaped portions. The controller 6000 may calculate a luminance of the droplet DS (e.g., the droplet DS as a whole) as an average value obtained by averaging the luminances of the lattice-shaped portions. The controller 6000 may compare the luminance of the droplet DS with a luminance of the test substrate where the droplet DS is not located. For example, the controller 6000 may calculate a luminance of the test substrate where the droplet DS is not located in the captured image. That is, the controller 6000 may calculate a luminance of a first area AR1 defined by an edge portion of the droplet DS and a luminance of a second area AR2 that is an area of the test member 13 where the droplet DS is not located. In this case, a method of calculating a luminance of the second area AR2 may involve dividing the second area AR2 into a plurality of lattice-shaped portions, calculating luminances of the lattice-shaped portions, and averaging the luminances of the lattice-shaped portions, like the method of calculating a luminance of the first area AR1. In this case, a planar shape of the second area AR2 may be almost the same as or similar to a planar shape of the first area AR1. That is, to select the second area AR2, the controller 6000 may select an area (e.g., a planar area) and/or a planar shape, which is the same as or similar to an area (e.g., a planar area) and/or a planar shape of the droplet DS, on a surface of the test member 13 where the droplet DS is not located, as the second area AR2. In another example, the entire area of the plane in the image including the first area AR1 may be deemed as the second area AR2. After the controller 6000 calculates the luminance of the first area AR1 and the luminance of the second area AR2 as described above, the controller 6000 may correct the luminance of the first area AR1 with the reference to the luminance of the second area AR2. In more detail, the controller 6000 may calculate a correction luminance of the first area AR1 by dividing the luminance of the first area AR1 by the luminance of the second area AR2. In this case, the controller 6000 may compare a preset luminance value based on the correction luminance of the first area AR1. The controller 6000 may compare the correction luminance of the first area AR1 with the preset luminance value and may calculate a concentration of particles contained in the droplet DS. In this case, a concentration of particles corresponding to the preset luminance value may be set in the controller 6000 as described above. In one or more embodiments, a concentration of particles according to the preset luminance value may be stored as a formula in the controller 6000. In this case, when the correction luminance of the first area AR1 is calculated, the controller 6000 may calculate a concentration of particles contained in the droplet DS. In one or more embodiments, the second area AR2 is an entire area including the first area AR1.

In one or more embodiments, referring to FIG. 7B, the controller 6000 may define the first area AR1 as an area including an edge of the droplet DS. For example, the controller 6000 may define the first area AR1 to surround an edge of the droplet DS (e.g., an edge of a planar shape of the droplet DS). In this case, the first area AR1 may have any of various suitable shapes. For example, the first area AR1 may have a circular shape, a polygonal shape, or an elliptical shape. As shown, for example, in FIG. 7B, a planar shape of the first area AR1 may be different from a planar shape of the droplet DS. In one or more embodiments, the first area AR1 may have an irregular shape such as a star shape. In this case, the first area AR1 is not limited thereto, and may have any suitable shape including the droplet DS (e.g., the planar shape of the droplet DS).

The controller 6000 may calculate a correction luminance of the first area AR1. In more detail, the controller 6000 may calculate an average value of a luminance of the first area AR1. The average value of the luminance of the first area AR1 may include not only a luminance of the planar shape of the droplet DS but also a luminance of a portion of the test member 13 where the droplet DS is not located.

The controller 6000 may calculate an average value of a luminance of the second area AR2 and then may calculate a correction luminance of the first area AR1 by dividing the average value of the luminance of the first area AR1 by the average value of the luminance of the second area AR2.

In one or more embodiments, as shown in FIG. 7C, the controller 6000 may calculate a correction luminance of the droplet DS except for a part of a planar shape of the droplet DS.

In more detail, the controller 6000 may divide the planar shape of the droplet DS from the image into the first area AR1 and a third area AR3 inside the first area AR1. In this case, the third area AR3 is an area of the planar shape of the droplet DS where light emitted by the lighting unit is reflected, and a luminance of the third area AR3 in the planar shape of the droplet DS may be higher than that of a portion of the planar shape of the droplet DS. The controller 6000 may define the first area AR1 by excluding the third area AR3 from the planar shape of the droplet DS. In this case, by excluding the third area AR3 having an abnormally high luminance, the correction luminance of the droplet DS calculated by the controller 6000 may be prevented or substantially prevented from being distorted due to the third area AR3. In one or more embodiments, an edge of the first area AR1 may be defined as described with reference to FIG. 7B.

In one or more embodiments, a correction luminance may be calculated by correcting a luminance of a captured image. For example, the controller 6000 may determine whether a luminance of a surface of the test member 13 is the same as a preset luminance based on the captured image. In this case, the luminance of the surface of the test member 13 of the captured image may vary whenever image capturing is performed according to an intensity of the lighting unit, a position of the lighting unit, a position of the lens, and the surface of the test member 13. In this case, the controller 6000 may calculate the luminance of the surface of the test member 13 from the captured image and then may adjust a luminance of the entire image to correspond to the preset luminance. In this case, the controller 6000 may calculate a luminance of the first area AR1 of FIGS. 7A through 7C, and the luminance of the first area AR1 may be a correction luminance.

When the correction luminance of the first area AR1 is calculated, the controller 6000 may calculate a concentration of particles contained in the droplet DS corresponding to the correction luminance of the first area AR1. In this case, the controller 6000 may calculate a concentration of particles contained in the droplet DS ejected by each of the first ejector 4000a, the second ejector 4000b, and the third ejector 4000c by performing the above process on each of the first ejector 4000a, the second ejector 4000b, and the third ejector 4000c.

The controller 6000 may store a calculated concentration of particles contained in a liquid, and then may move (e.g., linearly move) the first gantry 2000 on the guide member 1200 so that the first nozzle moving unit 3000a, the second nozzle moving unit 3000b, and the third nozzle moving unit 3000c are located to correspond to the display substrate S.

Next, the controller 6000 may move (e.g., linearly move) the first nozzle moving unit 3000a, the second nozzle moving unit 3000b, and the third nozzle moving unit 3000c on the first gantry 2000 so that the first ejector 4000a, the second ejector 4000b, and the third ejector 4000c are located to correspond to the display substrate S. For example, the controller 6000 may move the first nozzle moving unit 3000a, the second nozzle moving unit 3000b, and the third nozzle moving unit 3000c so that the first ejector 4000a, the second ejector 4000b, and the third ejector 4000c are above (e.g., above in the z direction) the display substrate S.

The first ejector 4000a, the second ejector 4000b, and the third ejector 4000c may supply the droplet DS to the display substrate S. In more detail, the controller 6000 may control the first ejector 4000a, the second ejector 4000b, and the third ejector 4000c to supply the droplet DS located at a position corresponding to the display substrate S to the display substrate S. In this case, the controller 6000 may control a concentration of all particles contained in a plurality of droplets DS dropped to one position of the display substrate S by controlling positions of the first ejector 4000a, the second ejector 4000b, and the third ejector 4000c.

In more detail, a total amount of the droplet DS dropped to each position of the display substrate S is set in the controller 6000. For example, the droplet DS may be dropped to one position of the display substrate S N times (N is a natural number, greater than 0) to form one layer. For example, the one layer formed on the display substrate S when the droplet DS is dropped may be an organic emission layer of FIG. 3, a color conversion layer of FIG. 3, a color conversion layer of FIG. 4, or a color filter of FIG. 4. In this case, the number of times the droplet DS should be supplied to a certain position of the display substrate S in order to form one layer located on the display substrate S may be set in the controller 6000. Also, an amount of particles that should be contained in one layer located on the display substrate S may be preset in the controller 6000. In particular, a concentration of particles that should be contained in one layer located on the display substrate S may be preset in the controller 6000.

To this end, the controller 6000 may supply the droplet DS to the display substrate S by reciprocating the first ejector 4000a, the second ejector 4000b, and the third ejector 4000c in a direction parallel to a side of the display substrate S.

In this case, the controller 6000 may adjust positions of the first ejector 4000a, the second ejector 4000b, and the third ejector 4000c to correspond to a total concentration of particles contained in the droplet DS for forming one layer on the display substrate S. For example, in general, a droplet may be supplied to the same portion of a display substrate by reciprocating the same ejector from among a plurality of ejectors multiple times in order to form one layer on the display substrate. In this case, because a concentration of particles contained in a droplet ejected from one of the plurality of ejectors is always constant, when a concentration of particles contained in a droplet ejected from one of the plurality of ejectors is different from a concentration initially set in the controller 6000, a total concentration of particles contained in a droplet for forming one layer located on a display substrate may not be matched. In order to solve this problem, the controller 6000 may select the droplet DS ejected to the same portion of the display substrate S from one of the first ejector 4000a, the second ejector 4000b, and the third ejector 4000c. In more detail, in order to match a total concentration of particles contained in one layer located on the display substrate S, when the first ejector 4000a, the second ejector 4000b, and the third ejector 4000c move in one direction, the droplet DS may be ejected from one ejector from among the first ejector 4000a, the second ejector 4000b, and the third ejector 4000c onto a point of the display substrate S; when the first ejector 4000a, the second ejector 4000b, and the third ejector 4000c move in the opposite direction and the same ejector from among the first ejector 4000a, the second ejector 4000b, and the third ejector 4000c passes through the point of the display substrate S, the droplet DS may not be ejected. For example, when the first ejector 4000a, the second ejector 4000b, and the third ejector 4000c move in one direction, if the first ejector 4000a is located again at a portion of the display substrate S onto which the first ejector 4000a ejects the droplet DS, the first ejector 4000a may not eject the droplet DS. Also, when the second ejector 4000b or the third ejector 4000c moves and corresponds to the portion of the display substrate S onto which the first ejector 4000a ejects the droplet DS, the controller 6000 may control the second ejector 4000b or the third ejector 4000c to eject the droplet DS. In one or more embodiments, when the first ejector 4000a should eject the droplet DS onto the same area of the display substrate S M times (M is a natural number greater than 0), the controller 6000 may control the first ejector 4000a to eject the droplet DS onto the same area of the display substrate S M−1 times, and then may control the second ejector 4000b or the third ejector 4000c to eject the droplet DS when the second ejector 4000b or the third ejector 4000c is located at the area of the display substrate S onto which the first ejector 4000a ejects the droplet DS.

Accordingly, the controller 6000 may select one of the first ejector 4000a, the second ejector 4000b, and the third ejector 4000c to match a total concentration of particles contained in one layer located on the display substrate S based on a calculated concentration of particles at each ejector, and may selectively supply the droplets DS having different particle concentrations to the same area of the display substrate S.

It is possible to infer a concentration somewhat similar to a concentration of particles actually contained in a droplet by using the above method of manufacturing a display apparatus and the above method of measuring a droplet.

In more detail, referring to FIG. 8A through FIG. 8D, a concentration of particles according to a correction luminance based on a luminance value measured by the measurer 20 is compared with a concentration of particles measured by a microscope or the like. Row1, Row2, Row3, and Row4 denote actual data, and NJI denotes a correction luminance based on a luminance value measured by the measurer 20. Also, the X-axis of each graph represents a nozzle number, the left Y-axis represents an actual concentration of particles, and the right Y-axis represents a correction luminance.

It is found that a correction luminance and a concentration of particles measured by a microscope or the like are similar to each other in each graph. In particular, it is found that a correlation between a correction luminance and a concentration of particles measured by a microscope or the like is about 0.92 or more. That is, it is found that when a calculated correction luminance corresponds to a concentration of actually measured particles, each nozzle has almost the same tendency. In this case, as a correlation is closer to 1, it may refer to an actual value and a measured and calculated value being more similar to each other. For example, it is found that a correlation is 0.98 in Embodiment 1 of FIG. 8A, a correlation is 0.97 in Embodiment 2 of FIG. 8B, a correlation is 0.98 in Embodiment 3 of FIG. 8C, and a correlation is 0.95 in Embodiment 4 of FIG. 8D.

When quantitative regression analysis is performed based on a correction luminance, a proportional relationship between the correction luminance and a concentration of particles may be obtained. Accordingly, when a correction luminance is calculated by the controller 6000 as described above, the controller 6000 may obtain a concentration of particles contained in each droplet DS based on the correction luminance.

Accordingly, the method of manufacturing a display apparatus and the method of measuring a droplet may accurately measure a concentration of particles contained in the droplet DS. Also, the method of manufacturing a display apparatus and the method of measuring a droplet may accurately match a concentration of particles. The method of manufacturing a display apparatus and the method of measuring a droplet may perform a precise process by accurately measuring a concentration of particles contained in the droplet DS and controlling an operation of the apparatus 1000.

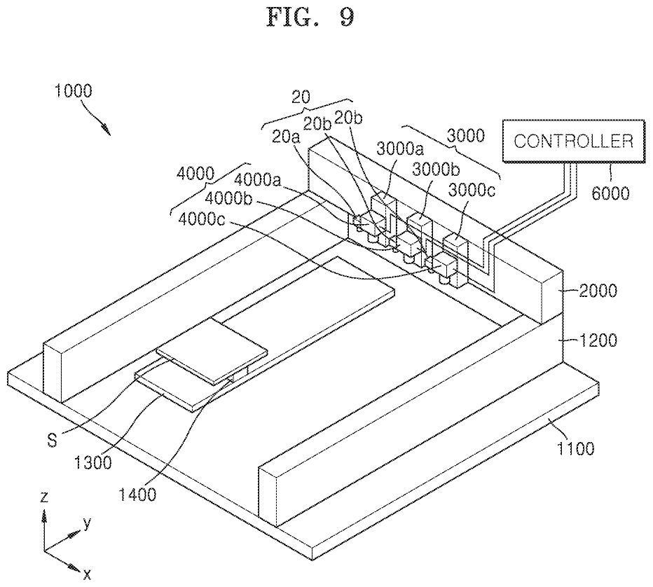

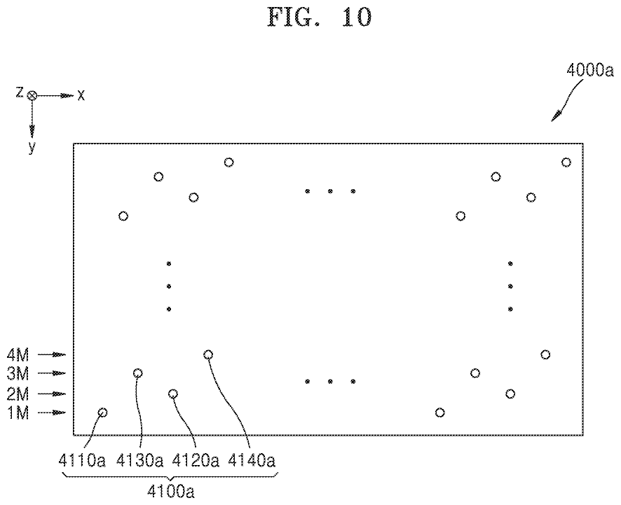

FIG. 9 is a perspective view illustrating an apparatus for manufacturing a display apparatus, according to one or more embodiments. FIG. 10 is a rear view illustrating a first ejector of FIG. 1.

Referring to FIGS. 9 and 10, the apparatus 1000 may include the stage 1100, the first gantry 2000, the moving unit 3000, the droplet ejector 4000, the measurer 20, and the controller 6000. In this case, the stage 1100, the first gantry 2000, the moving unit 3000, the droplet ejector 4000, and the controller 6000 are the same as or similar to those of FIG. 5, and thus a detailed description may not be repeated.

The measurer 20 may be movably connected to the first gantry 2000. In this case, the measurer 20 may be connected to the moving unit 3000 and may move along with the droplet ejector 4000. In one or more embodiments, the measurer 20 may include a separate moving unit similar to the moving unit 3000 on the first gantry 2000, may be located on the moving unit 3000, and may move (e.g., linearly move) along the first gantry 2000. However, for convenience of explanation, the following will be described in more detail assuming that the measurer 20 is located on the moving unit 3000.

At least one measurer 20 may be provided. For example, one measurer 20 may be provided, and the measurer 20 may be located on the first nozzle moving unit 3000a, the second nozzle moving unit 3000b, or the third nozzle moving unit 3000c. In one or more embodiments, a plurality of measurers 20 may be provided, and each of the plurality of measurers 20 may be located on each nozzle moving unit. For example, the measurer 20 may include a first measurer 20a located on the first nozzle moving unit 3000a, a second measurer 20b located on the second nozzle moving unit 3000b, and a third measurer 20c located on the third nozzle moving unit 3000c. In this case, the first measurer 20a may move along with the first ejector 4000a, the second measurer 20b may move along with the second ejector 4000b, and the third measurer 20c may move along with the third ejector 4000c. For convenience of explanation, the following will be described in more detail assuming that the measurer 20 includes the first measurer 20a through the third measurer 20c.

Each of the first ejector 4000a through the third ejector 4000c may supply a droplet to the display substrate S. In one or more embodiments, in a state where the display substrate S is fixed, the first ejector 4000a through the third ejector 4000c may supply the droplet to the display substrate S while reciprocating in one direction (e.g., the y direction of FIG. 9). Also, the first ejector 4000a through the third ejector 4000c may move by a certain interval in a longitudinal direction of the first gantry 2000 and then may supply the droplet to another portion of the display substrate S while moving in the same direction as the above direction (e.g., the y direction of FIG. 9). In one or more embodiments, the first ejector 4000a through the third ejector 4000c may move in the x direction of FIG. 9 on the display substrate S, and may supply the droplet to the display substrate S while the display substrate S moves in the y direction. For convenience of explanation, the following will be described in more detail assuming that the display substrate S reciprocates in the y direction and the first ejector 4000a through the third ejector 4000c supply the droplet to the display substrate S while moving by a certain interval in the x direction of FIG. 9.

Each of the first ejector 4000a through the third ejector 4000c may include a nozzle. In this case, because the first ejector 4000a through the third ejector 4000c are formed to be the same as or similar to each other, the first ejector 4000a will be mainly described in more detail.

The first ejector 4000a may include at least one first nozzle 4100a. For example, the first ejector 4000a may include one first nozzle 4100a. In one or more embodiments, the first ejector 4000a may include a plurality of first nozzles 4100a. In this case, the plurality of first nozzles 4100a may be spaced from one another, and may be arranged in a zigzag shape. For example, the plurality of first nozzles 4100a may include a 1-1^{th} nozzle 4110a located in a first column 1M located in a lower portion of FIG. 10. Also, the plurality of first nozzles 4100a may include a 1-2^{th} nozzle 4120a located in a second column 2M. The plurality of first nozzles 4100a may include a 1-3^{th} nozzle 4130a located in a third column 3M, and a 1-4^{th} nozzle 4140a located in a fourth column 4M. In this case, the 1-1^{th} nozzle 4110a through the 1-4^{th} nozzle 4140a may constitute one nozzle group, and a plurality of nozzle groups may be provided to be spaced from one another in the x direction of FIG. 10. Also, the nozzle groups may be located to be spaced from one another in the y direction of FIG. 10. In this case, the 1-1^{th} nozzles 4110a of the nozzle groups spaced from one another in the y direction of FIG. 10 may be arranged obliquely, rather than linearly, in the y direction. In this case, the 1-2^{th} nozzle 4120a, the 1-3^{th} nozzle 4130a, and the 1-4^{th} nozzle 4140a of each nozzle group may be arranged in the same manner as that of the 1-1^{th} nozzle 4110a. That is, nozzles may be aligned in the x direction, and may not be aligned in the y direction but may be aligned in a direction between the x direction and the y direction.

The 1-1^{th} nozzle 4110a through the 1-4^{th} nozzle 4140a of each nozzle group may supply the droplet to different areas of the display substrate S. In one or more embodiments, at least two of the 1-1^{th} nozzle 4110a through the 1-4^{th} nozzle 4140a of each nozzle group may supply the droplet to the same area of the display substrate S. In one or more embodiments, at least one of the 1-1^{th} nozzle 4110a through the 1-4^{th} nozzle 4140a of a first nozzle group and at least one of the 1-1^{th} nozzle 4110a through the 1-4^{th} nozzle 4140a of a second nozzle group that is different from the first nozzle group may supply the droplet to the same area of the display substrate S. For convenience of explanation, the following will be described in more detail assuming that one of the 1-1^{th} nozzle 4110a through the 1-4^{th} nozzle 4140a of one nozzle group supplies the droplet to one area of the display substrate S.

The apparatus 1000 may locate the display substrate S on the stage 1100, may supply the droplet to the display substrate S through each of the first ejector 4000a through the third ejector 4000c, may capture an image of the display substrate S by using the measurer 20, and then may calculate a concentration of particles contained in the droplet. In this case, a method of calculating the concentration of the particles contained in the droplet is the same as or similar to that described with reference to FIG. 5, and thus a detailed description thereof may not be repeated.

In the above case, in order to calculate a concentration of particles, a droplet may be supplied through all nozzles of all ejectors to the entire area of the display substrate S or a certain area of the display substrate S and then may be measured by a measurer 20 to measure a concentration of particles contained in the droplet ejected through each nozzle.

The number of times the droplet is ejected through each nozzle and a number of a nozzle through which the droplet is supplied to one area of the display substrate S may be changed based on the measured concentration. In more detail, when the droplet should be supplied to one area of the display substrate S, the number of times the droplet is dropped and a nozzle passing through the one area of the display substrate S may be preset in the controller 6000. For example, it may be preset in the controller 6000 that the droplet should be dropped 10 times in order to supply a droplet of a desired or suitable volume to one area of the display substrate S. In this case, it may be preset in the controller 6000 that the 1-1^{th} nozzle 4110a is located over the display substrate S 5 times, the 1-3^{th} nozzle 4130a is located over the display substrate S 5 times, and whenever the 1-1^{th} nozzle 4110a and the 1-3^{th} nozzle 4130a are located over a portion of the display substrate S to which the droplet should be supplied, each of the 1-1^{th} nozzle 4110a and the 1-3^{th} nozzle 4130a supplies the droplet to the display substrate S once. In this case, the controller 6000 may adjust the number of times the droplet is supplied to the display substrate S from the 1-1^{th} nozzle 4110a to 3 times and the number of times the droplet is supplied to the display substrate S from the 1-3^{th} nozzle 4130a to 7 times according to a concentration of particles contained in the droplet supplied by each nozzle. In one or more embodiments, the controller 6000 may control, when the 1-1^{th} nozzle 4110a is located over the display substrate S to which the droplet should be supplied, the 1-1^{th} nozzle 4110a to supply the droplet to the display substrate S 5 times as preset above, and when at least one of the 1-1^{th} nozzle 4110a, the 1-2^{th} nozzle 4120a, or the 1-4^{th} nozzle 4140a instead of the 1-3^{th} nozzle 4130a is located over the display substrate S to which the droplet should be supplied, at least one of the 1-1^{th} nozzle 4110a, the 1-2^{th} nozzle 4120a, or the 1-4^{th} nozzle 4140a to supply the droplet to the display substrate S. In addition, the above process may be performed for each ejector. Also, the above process may be performed by selecting nozzles of a plurality of nozzles groups of one ejector. In this case, the controller 6000 may form a layer having a set concentration when forming one area of the display substrate S (e.g., an organic emission layer inside an opening portion of a pixel-defining film, each color conversion layer, or each color filter), and may uniformize concentrations of particles in layers formed by using the droplet uniformly distributed over the entire area of the display substrate S. In this case, the layers formed by using the droplet may be spaced from one another, and a moire phenomenon occurring due to different concentrations of particles contained in the droplet may be prevented or reduced.

The above process may be performed on one display substrate S, or may be performed on a plurality of display substrates S. For example, the above process may be performed on one display substrate S, and a movement of the first ejector 4000a over other display substrates S may be controlled based on the above process. In addition, when the process on one display substrate S is completed and then a result is fed back to the controller 6000, a concentration of particles contained in the droplet ejected through each ejector or a nozzle of each ejector may be monitored in real time.

Accordingly, the apparatus 1000 may control a concentration of particles to be uniform over an entire surface.

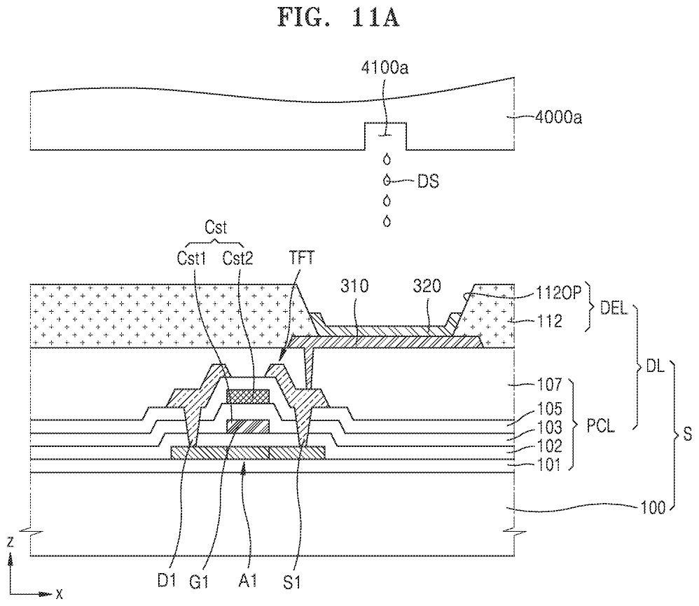

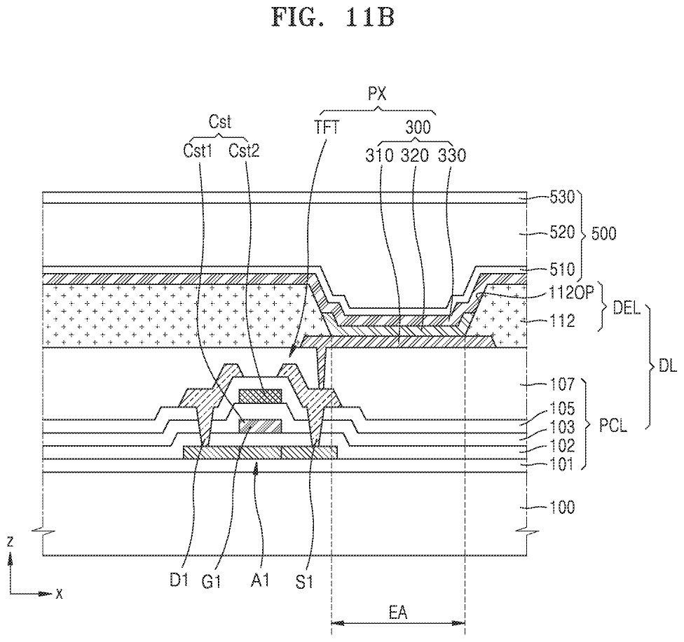

FIGS. 11A and 11B are cross-sectional views illustrating a method of manufacturing a display apparatus, according to one or more embodiments.

Referring to FIGS. 11A and 11B, the apparatus 1000 of FIG. 5 or 9 may be used to form the intermediate layer 320 including a quantum dot emission layer. In this case, the intermediate layer 320 may be formed by supplying the droplet DS from at least one of the first ejector 4000a through the third ejector 4000c. Particles (e.g., scatterers) may be further included in the droplet DS. The apparatus 1000 may eject the droplet DS (e.g., the quantum dot emission layer) including the particles (e.g., scatterers) into the opening portion 112OP. However, for convenience of explanation, the following will be described in more detail assuming that the apparatus 1000 locates the the droplet DS including the particles in the opening portion 112OP.

In this case, the first ejector 4000a through the third ejector 4000c may supply the droplets DS including quantum dot emission layers emitting light of different colors. For example, one of the first ejector 4000a through the third ejector 4000c may supply the droplet DS including a red quantum dot emission layer. Another one of the first ejector 4000a through the third ejector 4000c may supply the droplet DS including a green quantum dot emission layer. Another one of the first ejector 4000a through the third ejector 4000c may supply the droplet DS including a blue quantum dot emission layer.

In this case, in order to form the intermediate layer 320 that emits light of the same color, at least one of the first ejector 4000a through the third ejector 4000c may be used. For convenience of explanation, the following will be described below in more detail assuming that the first nozzle 4100a of the first ejector 4000a is used to form the intermediate layer 320 that emits light of the same color.

The first nozzle 4100a of the first ejector 4000a may supply the droplet DS to the display substrate S. The droplet DS may be inserted into the opening portion 112OP of the pixel-defining film 112. In this case, the display substrate S may include layers from the substrate 100 to the pixel-defining film 112.

In this case, a concentration of particles contained in the intermediate layer 320 may be controlled to be the same as or similar to a preset concentration and concentrations of particles contained in the intermediate layers 320 of pixels emitting light of the same color may also be controlled to be uniform over the display substrate S as described above. That is, a nozzle through which the droplet DS is supplied to the opening portion 112OP may be changed or the number of times the droplet DS is supplied through a nozzle may be controlled.

In more detail, a display apparatus may include a plurality of pixels, and the plurality of pixels PX may emit light of different colors. For example, the plurality of pixels PX may include pixels that emit red light, green light, and blue light. In this case, at least one of the red pixel, the green pixel, or the blue pixel may be provided in plurality. For convenience of explanation, a plurality of red pixels, a plurality of green pixels, and a plurality of blue pixels are provided, and a method of forming a plurality of blue pixels will be described in more detail.

In this case, when a plurality of blue pixels are formed, nozzles for supplying the droplet DS to the blue pixels may be different from one another. For example, nozzles for forming a first blue pixel from among the plurality of blue pixels may be the 1-1^{th} nozzle 4110a and the 1-2^{th} nozzle 4120a of FIG. 10. In contrast, nozzles for forming a second blue pixel from among the plurality of blue pixels which is located at a position different from that of the first blue pixel may be the 1-2^{th} nozzle 4120a and the 1-3^{th} nozzle 4130a of FIG. 10. In this case, because concentrations of the droplet DS ejected through the 1-1^{th} nozzle 4110a, the 1-2^{th} nozzle 4120a, and the 1-3^{th} nozzle 4130a are different from one another, a concentration of particles contained in the intermediate layer 320 formed by supplying the droplet DS to the first blue pixel and a concentration of particles contained in the intermediate layer 320 formed by supplying the droplet DS to the second blue pixel may be different from each other. This may repeatedly occur in a plurality of pixels PX that emit light of the same color, and the intermediate layers 320 having the same particle concentration may be aligned in a movement direction of the moving unit 3000 (see FIG. 5 or 9) or the droplet ejector 4000 or a movement direction of the display substrate S. In contrast, pixels PX arranged in a direction different from a movement direction of the display substrate S and are adjacent to each other may have different particle concentrations. In this case, pixels PX adjacent to each other, located in different columns, and emitting light of the same color may have a problem in that fine lines are shown when light is emitted or light is incident due to a concentration difference.

In order to solve the problem, a luminance of the droplet DS ejected from each nozzle measured as described above may be calculated and concentrations of particles contained in total droplets supplied to a position corresponding to each pixel PX may be adjusted based on the calculated luminance of the droplet DS.

For example, when the droplet ejector 4000 supplies the droplet DS to the first blue pixel, the droplet DS may be supplied from the 1-1^{th} nozzle 4110a and the 1-2^{th} nozzle 4120a the same number of times. However, when the droplet ejector 4000 supplies the droplet DS to the second blue pixel, instead of supplying the droplet from 1-2^{th} nozzle 4120a and the 1-3^{th} nozzle 4130a, the 1-1^{th} nozzle 4110a may be controlled to be located over the second blue pixel and the droplet DS may be supplied from the 1-1^{th} nozzle 4110a, and then when the 1-2^{th} nozzle 4120a is located over the second blue pixel, the droplet DS may be supplied.

In one or more embodiments, in the above case, the droplet DS may be supplied from the 1-1^{th} nozzle 4110a to the second blue pixel, and then the droplet DS may be sequentially supplied from the 1-2^{th} nozzle 4120a and the 1-3^{th} nozzle 4130a.

In one or more embodiments, in the above case, the droplet DS may be supplied from the 1-4^{th} nozzle 4140a to the second blue pixel, and then the droplet DS may be supplied from at least one of the 1-1^{th} nozzle 4110a, the 1-2^{th} nozzle 4120a, or the 1-3^{th} nozzle 4130a.

The above process is not limited thereto, and a concentration of particles contained in the intermediate layer 320 located in each pixel PX may be controlled by controlling an amount (e.g., the number of the droplet DS) ejected at one time from each nozzle or by reducing the number of times the droplet DS is ejected to a certain portion from each nozzle. Also, in other cases, a concentration of particles may be controlled by changing a path of the droplet ejector 4000.

Accordingly, according to the method of manufacturing a display apparatus, concentrations of particles contained in intermediate layers 320 located on the display substrate S and included in pixels PX that emit light of the same color may be uniform over an entire surface of the display substrate S.

After the intermediate layer 320 is formed as described above, an intermediate layer 320 of a different color located on the display substrate S may be formed. In this case, the intermediate layers 320 for emitting light of different colors may be formed by using different nozzles or different ejectors.

Next, the common electrode 330, the first inorganic encapsulation layer 510, the organic encapsulation layer 520, and the second inorganic encapsulation layer 530 may be sequentially formed on the display substrate S including the intermediate layer 320 to complete the manufacture of the display apparatus.

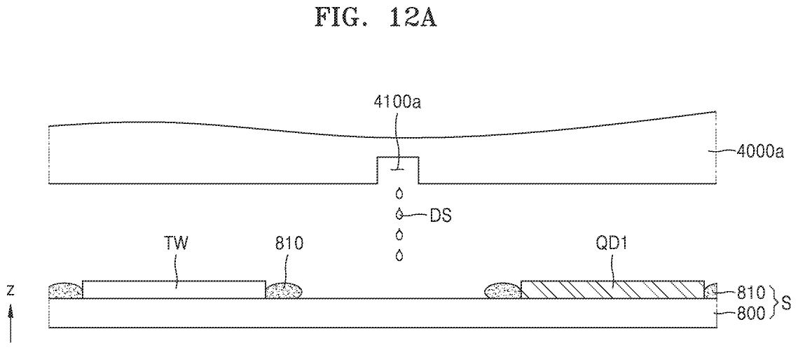

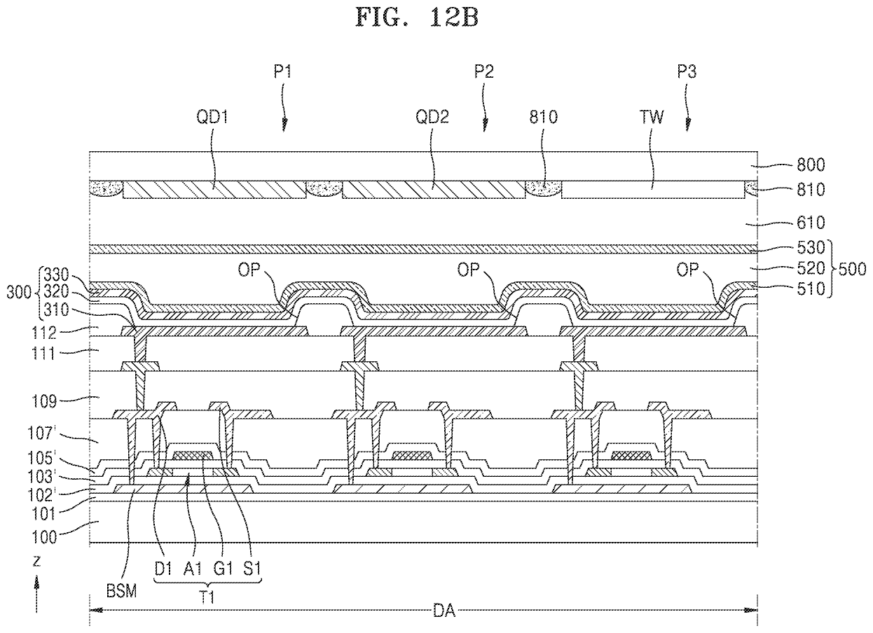

FIGS. 12A and 12B are cross-sectional views illustrating a method of manufacturing a display apparatus, according to one or more embodiments.

Referring to FIGS. 12A and 12B, the display substrate S may include the upper substrate 800 and the light-blocking patterns 810.

The display substrate S may be located on the stage 1100 of FIG. 5 or 9, and then at least one of the first or second color conversion layers QD1 and QD2 and the transmissive layer TW may be formed between the light-blocking patterns 810. For convenience of explanation, the following will be described in more detail assuming that the second color conversion layer QD2 is formed. Also, the following will be described in more detail assuming that the second color conversion layer QD2 is formed through the first nozzle 4100a of the first ejector 4000a.

When the droplet DS is supplied from the first nozzle 4100a of the first ejector 4000a in order to form the second color conversion layer QD2, the controller 6000 may select the first nozzle 4100a that should supply the droplet DS from among the plurality of first nozzles 4100a to correspond to a volume of the droplet DS used to form the second color conversion layer QD2 and a concentration of particles to be contained in the second color conversion layer QD2 based on concentrations of particles contained in the droplet DS ejected from the plurality of first nozzles 4100a, and may adjust a position of the first ejector 4000a so that the selected first nozzle 4100a passes through a portion of the display substrate S on which the second color conversion layer QD2 should be formed. Also, the controller 6000 may adjust the number of times the droplet DS is ejected through the selected first nozzle 4100a. The controller 6000a may adjust an amount (e.g. number) of the droplet DS ejected once through the selected first nozzle 4100a. These may be stored as a table in the controller 6000 or may be stored as a formula calculated through a separate program in the controller 6000.

The above process may also be performed in the same manner on the second color conversion layer QD2 located at another position of the display substrate S. In this case, the above process may be performed in the same manner on the first color conversion layer QD1 and the transmissive layer TW, in addition to the second color conversion layer QD2.

Accordingly, concentrations of particles contained in a plurality of first color conversion layers QD1, concentrations of particles contained in a plurality of second color conversion layers QD2, or concentrations of particles contained in a plurality of transmissive layers TW corresponding to pixels that emit light of the same color may be uniform over an entire surface of the display substrate S.

When the first and second color conversion layers QD1 and QD2 are completely formed on the light-blocking patterns 810, the filler 610 may be located on the first and second color conversion layers QD1 and QD2 and the transmissive layer TW and may be coupled to a display panel, to complete the manufacture of the display apparatus. In this case, the display panel may include layers from the substrate 100 to the second inorganic encapsulation layer 530.

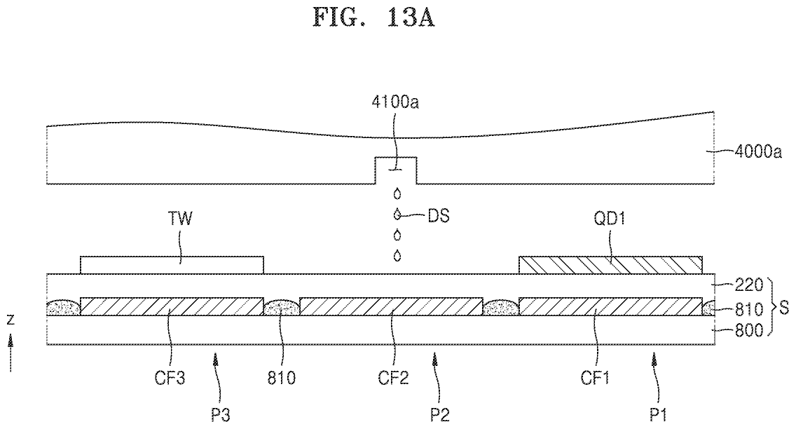

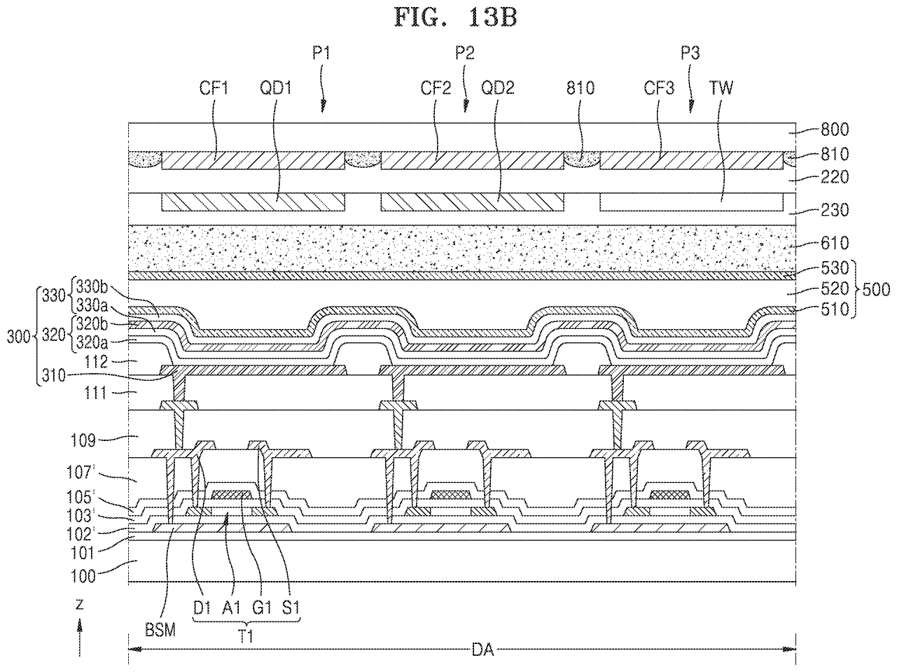

FIGS. 13A and 13B are cross-sectional views illustrating a method of manufacturing a display apparatus, according to one or more embodiments.

Referring to FIGS. 13A and 13B, the display substrate S may include the upper substrate 800, the light-blocking patterns 810, the first through third color filters CF1, CF2, and CF3, and the protective layer 220. In this case, the display substrate S may be manufactured by forming the light-blocking patterns 810 on the upper substrate 800, locating the first through third color filters CF1, CF2, and CF3 between the light-blocking patterns 810, and forming the protective layer (or the protective film) 220 on the first through third color filters CF1, CF2, and CF3 and the light-blocking patterns 810.

At least one of the first or second color conversion layers QD1 and QD2 and the transmissive layer TW may be formed on the display substrate S by the apparatus 1000 of FIG. 5 or 9. For convenience of explanation, the following will be described in more detail assuming that the second color conversion layer QD2 is formed on the display substrate S. Also, the following will be described in more detail assuming that the second color conversion layer QD2 is formed through the first nozzle 4100a of the first ejector 4000a.

The second color conversion layer QD2 may be formed on the display substrate S by supplying the droplet DS through the first nozzle 4100a. In this case, the controller 6000 may control a number of a nozzle that passes through a portion of the display substrate S on which the second color conversion layer QD2 is to be located and the number of times the droplet DS is ejected to correspond to a concentration of particles to be contained in the second color conversion layer QD2.

In this case, the controller 6000 may control the moving unit 3000 so that, instead of a preset one of the plurality of first nozzles 4100a, another one of the plurality of first nozzles 4100a passes through a portion of the display substrate S on which the second color conversion layer QD2 is to be located is selected to form the second color conversion layer QD2. In one or more embodiments, when a preset one of the plurality of first nozzles 4100a passes through a portion of the display substrate S on which the second color conversion layer QD2 is to be located, the controller 6000 may not operate the preset one of the plurality of first nozzles 4100a to eject the droplet DS, and when another preset one of the plurality of first nozzles 4100a passes through the portion of the display substrate S on which the second color conversion layer QD2 is to be located, the controller 6000 may operate the other preset one of the plurality of first nozzles 4100a to eject the droplet DS. Also, the number of times the droplet DS is ejected from one of the plurality of first nozzles 4100a located over the portion of the display substrate S on which the second color conversion layer QD2 is to be located may be adjusted.

The above process may be repeatedly performed on an entire surface of the display substrate S, to form a plurality of second color conversion layers QD2 on the display substrate S. In this case, concentrations of particles contained in the second color conversion layers QD2 may be almost the same over the entire surface of the display substrate S.

Also, the above process may be performed in the same manner on the first color conversion layer QD1 and the transmissive layer TW.

Accordingly, when the first and second color conversion layers QD1 and QD2 emitting light of the same color are formed through the above process, concentrations of particles contained in the first and second color conversion layers QD1 and QD2 emitting light of the same color may be adjusted to be uniform over the entire surface of the display substrate S.

As described above, the first and second color conversion layers QD1 and QD2 and the transmissive layer TW may be formed on the display substrate S and then the additional protective layer 230 may be formed on the first and second color conversion layers QD1 and QD2 and the transmissive layer TW, or the additional protective layer 230 and the filler 610 may be formed and the display substrate S may be coupled to a display panel. In this case, the display panel may include layers from the substrate 100 to the second inorganic encapsulation layer 530 of FIG. 13B.

Although the formation of the first and second color conversion layers QD1 and QD2 has been described in more detail, the color filter CF1, CF2, and CF3 may also be formed by the apparatus 1000 of FIG. 5 or 9. In this case, the display substrate S may include the upper substrate 800 and the light-blocking patterns 810. In this case, when particles are contained in the first through third color filters CF1, CF2, and CF3, concentrations of particles contained in the first through third color filters CF1, CF2, and CF3 may be adjusted in a manner that is the same as or similar to that described above.

After the first through third color filters CF1, CF2, and CF3 are formed, layers from the protective layer 220 to the additional protective layer 230 or layers from the protective layer 220 to the filler 610 may be formed on the display substrate S and the first through third color filters CF1, CF2, and CF3 and may be coupled to the display panel.

Accordingly, in the above case, concentrations of particles contained in the first through third color filters CF1, CF2, and CF3 of the same color may be uniform on the display substrate S.

As described above, according to one or more embodiments, a concentration of particles contained in a droplet may be precisely measured based on a luminance of the droplet. Also, according to one or more embodiments, a concentration of particles contained in a droplet ejected from an ejector may be measured in real time.

Also, according to one or more embodiments, the precision of an apparatus for manufacturing a display apparatus may be improved. Also, the efficiency of the apparatus for manufacturing a display apparatus may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims, and equivalents thereof.

What is claimed is:

1. A method of manufacturing a display apparatus, the method comprising:
supplying, from an ejector, a droplet onto a plane;
capturing an image of the droplet;
calculating a first luminance of a first area of the plane, the first area comprising a planar area of the droplet; and
calculating a concentration of particles contained in the droplet based on the first luminance.

2. The method of claim 1, further comprising calculating a second luminance of a second area of the plane.

3. The method of claim 2, wherein the concentration of the particles contained in the droplet is calculated based on a correction luminance obtained by dividing the first luminance by the second luminance.

4. The method of claim 2, wherein the second area is an area where the droplet is not located.

5. The method of claim 4, wherein a planar shape of the second area corresponds to a planar shape of the first area.

6. The method of claim 2, wherein the second area is an entire area of the plane comprising the first area.

7. The method of claim 1, wherein the first area comprises an edge having a planar shape of the droplet.

8. The method of claim 1, wherein an edge of the planar area of the droplet is located inside the first area, and
wherein the first area is larger in area than the planar area of the droplet.

9. The method of claim 1, further comprising:
defining a third area located inside the first area; and
calculating the first luminance of the first area excluding the third area.

10. The method of claim 9, wherein the third area is an area where reflection occurs.

11. The method of claim 1, wherein the first luminance is an average luminance of the first area.

12. The method of claim 1, further comprising controlling an operation of the ejector according to the concentration of the particles.

13. The method of claim 1, wherein the plane is a plane of a test member or a plane of a display substrate.

14. The method of claim 13, further comprising ejecting another droplet onto the display substrate based on the concentration of the particles contained in the droplet.

15. The method of claim 14, wherein the droplet comprises quantum dots.

16. The method of claim 14, further comprising forming a color filter.

17. The method of claim 14, further comprising ejecting droplets having different concentrations onto a same portion of the display substrate.

18. The method of claim 14, wherein the ejector comprises a plurality of nozzles, and
wherein a concentration of a respective one of droplets is calculated for each of the plurality of nozzles.

19. The method of claim 18, wherein droplets are supplied to a same portion of the display substrate through at least two nozzles from among the plurality of nozzles, the at least two nozzles having different particle concentrations in the respective ones of the droplets.

20. The method of claim 14, wherein a plurality of ejectors is provided, and
wherein a concentration of a respective one of droplets is calculated for each of the plurality of ejectors.

21. The method of claim 20, wherein droplets are supplied to a same portion of the display substrate through at least two ejectors from among the plurality of ejectors, the at least two ejectors having different particle concentrations in the respective ones of the droplets.

22. A method of manufacturing a display apparatus, the method comprising:
ejecting a droplet onto a plane through each of a plurality of nozzles and capturing an image of the droplet;
setting a first area comprising the droplet in the image;
calculating a first luminance of the first area;
setting a second area different from the first area on the plane, and calculating a second luminance of the second area;
calculating a correction luminance by using the first luminance and the second luminance, and calculating a concentration of particles contained in the droplet ejected through each of the plurality of nozzles based on the correction luminance;
supplying droplets multiple times to a first portion and a second portion of a display substrate respectively corresponding to a first emission area and a second emission area that are located at different positions to emit light of a same color, to form a first layer on the first portion and a second layer on the second portion; and
selecting a nozzle through which a droplet is supplied to the first emission area or the second emission area from among the plurality of nozzles based on the correction luminance of the droplet ejected through each nozzle so that, when the first layer and the second layer are formed, a concentration of particles contained in the first layer and a concentration of particles contained in the second layer are uniform.

23. The method of claim 22, further comprising calculating the first luminance of the first area excluding a third area that is located inside the first area and where reflection occurs.

24. The method of claim 22, wherein the droplet comprises quantum dots.

25. The method of claim 22, wherein the particles comprise scatterers.

26. The method of claim 22, wherein a planar area of the droplet is located inside the first area, and
wherein the first area is equal to or larger than the planar area of the droplet.

27. The method of claim 22, wherein the correction luminance is calculated by dividing the first luminance by the second luminance.

28. An apparatus for manufacturing a display apparatus, the apparatus comprising:
a test table adapted to support a test member or a substrate, the test member or the substrate being adapted to receive a droplet;
a measurer spaced from the test table, the measurer being configured to capture an image of the droplet on the substrate or the test member; and
a controller configured to calculate a first luminance of a first area comprising a planar area of the droplet based on the image of the droplet captured by the measurer, and to calculate a concentration of particles in the droplet based on the first luminance of the first area.

29. The apparatus of claim 28, wherein the controller is further configured to calculate a correction luminance by dividing the first luminance by a second luminance of a second area of the test member or a second luminance of a second area of the substrate, and to calculate the concentration of the particles in the droplet based on the correction luminance.

30. The apparatus of claim 28, further comprising an ejector configured to eject the droplet.

31. The apparatus of claim 30, wherein the controller is further configured to control an operation of the ejector according to the concentration of the particles in the droplet.

32. The apparatus of claim 28, wherein a planar area of the droplet in the image is located inside the first area.

33. The apparatus of claim 28, wherein a planar shape of the droplet in the image corresponds to a planar shape of the first area.

34. The apparatus of claim 28, wherein the controller is further configured to calculate a luminance of the first area excluding a third area that is located inside the first area.

35. The apparatus of claim 34, wherein the third area is an area where light emitted from the measurer is reflected by the droplet.

36. A method of measuring a droplet, the method comprising:
measuring a first luminance of a first area comprising a planar area of a droplet located in a plane; and
calculating a concentration of particles contained in the droplet based on the first luminance.

37. The method of claim 36, further comprising calculating a second luminance of a second area located in the plane.

38. The method of claim 37, wherein a correction luminance is calculated by dividing the first luminance by the second luminance, and the concentration of the particles in the droplet is calculated based on the correction luminance.

39. The method of claim 36, wherein a planar area of the droplet in an image is located inside the first area.

40. The method of claim 36, wherein a planar shape of the droplet in an image corresponds to a planar shape of the first area.

41. The method of claim 36, wherein the first luminance of the first area excluding a third area that is located inside the first area is calculated.
